(19) United States
(12) Patent Application Publication
(10) Pub. No.: US 2016/0268535 A1
(43) Pub. Date: Sep. 15, 2016

(54) ORGANIC LIGHT-EMITTING COMPONENT

(71) Applicant: OSRAM OLED GMBH, Regensburg (DE)

(72) Inventors: Andreas Rausch, Regensburg (DE); Carola Diez, Regensburg (DE)

(73) Assignee: OSRAM OLED GmbH, Regensburg (DE)

(21) Appl. No.: 15/030,877

(22) PCT Filed: Oct. 15, 2014
(86) PCT No.: PCT/EP2014/072159

§ 371 Date: Apr. 21, 2016

(30) Foreign Application Priority Data
Oct. 21, 2013 (DE) 10 2013 111 552.7

(51) Int. Cl. H01L 51/50; C09K 11/06

(52) U.S. Cl. CPC H01L 51/5036; H01L 51/5044; H01L 51/5016; C09K 11/06; H01L 2251/5376; H01L 51/0087

(57) ABSTRACT

In various embodiments, an organic light-emitting component is provided. The organic light-emitting component has a carrier, a first electrode above the carrier, an organic functional layer structure above the first electrode and a second electrode above the organic functional layer structure. The organic functional layer structure includes first organic emitters that emit in the blue spectral region, second organic emitters that emit in the green spectral region and third organic emitters that emit in the red spectral region. The third organic emitters include a molecule having at least one ligand having a plurality of ligand units. The third organic emitters have the property that, on emission of light, a charge transfer takes place from one of the ligand units of the ligand of one of the molecules to another of the ligand units of the same ligand of the same molecule and the corresponding singlet-triplet splitting is small.

### RELATED APPLICATIONS

The present application is a national stage entry according to 35 U.S.C. §371 of PCT application No.: PCT/EP2014/072159 filed on Oct. 15, 2014, which claims priority from German application No.: 10 2013 111 552.7 filed on Oct. 21, 2013, and is incorporated herein by reference in its entirety.

### TECHNICAL FIELD

Various embodiments relate to an organic light-emitting component.

### BACKGROUND

An organic light-emitting component, for example an organic light-emitting diode (OLED), which emits light, for example, in the white spectral region, or emits in the white for short, may have, for example, a plurality of emitter layers including emitters which emit in the blue, in the green and in the red or in the blue and in the red/green, especially in the corresponding spectral range. The emitter layers may also be referred to as emission layers. The emitter layers may or may not be stacked. In this context, “stacked” means that the individual emitter layers are coupled to one another via a charge carrier pair generation layer sequence (CGL).

The disadvantage is that it is not possible with the emitters known to date, in this concept, to cover the entire spectral range with only 3 different emitters so as to result in a colour rendering index (CRI) of greater than 90. The colour rendering index is understood to mean a photometric parameter with which the quality of the colour rendering of light sources of equal correlated colour temperature can be described. The abbreviated notation for the colour rendering index is Rₐ. In this abbreviation, the index a stands for “allgemeine” [general] colour rendering index, which takes account only of the values of the first eight test colours (R₁, R₂, . . . , R₈) according to DIN.

For example, the emission of an OLED when a bright red emitter in the deep red spectral region is used is insufficient, and so the colour renderings of the R₈ and R₉ values (lilac violet and saturated red) in particular are too low. If an attempt is made to solve this problem by using a deep red emitter which covers the long-wave flank to a sufficient degree, a gap generally arises between the emission bands of the emitters that emit in the green spectral region and those which emit in the red spectral region, meaning that the emission intensity in this region is too low. This has an adverse effect on the colour rendering index.

Known OLEDs having a CRI greater than 90 regularly have more than three emitter layers, for example five. More particularly, additional emitter layers are formed, which ensure the additional emission in the individual wavelength ranges. However, the additional emitter layers can contribute to lowering of the efficiency of the OLED. For example, an OLED having a CRI of 93 may have five emitter layers each including one emitter and have only a low efficiency of, for example, 23 lm/W. The additional emitter layers may also contribute to producibility of the corresponding OLED only in a relatively complex manner and therefore at relatively high cost compared to an OLED having two or three emitter layers. For example, the production of LEDs of such complicated structure may require a laboratory with a cluster tool or the use of additional sources for several materials in an inline system.

An alternative to the additional emitter layers for realization of a high CRI is, for example, the combined utilization of high-energy monomer emission and low-energy excimer or exciplex emission. However, this approach too generally achieves only very low efficiencies of less than 10 lm/W.

It is also possible to combine a plurality of colour units with one another by means of stacking, for example multiple stacking, of a plurality of OLEDs. However, this considerably complicates the production and/or results in longer cycle times and causes additional costs as a result. Moreover, in the case of additional emitter materials, significant spectral colour ageing and efficiency-reducing energy transfers and quenching processes can occur.

### SUMMARY

In various embodiments, an organic light-emitting component having a high CRI, for example a CRI greater than 90, is provided, and/or one having a high efficiency, and/or one having a maximum of two light-emitting layers and/or a maximum of three emitters, and/or one which can be produced inexpensively, for example in an inline process.

In various embodiments, an organic light-emitting component is provided. The organic light-emitting component has a substrate. A first electrode is formed above the substrate. An organic functional layer structure is formed above the first electrode. A second electrode is formed above the organic functional layer structure. The organic functional layer structure includes first organic emitters that emit in the blue spectral region, second organic emitters that emit in the green spectral region and third organic emitters that emit in the red spectral region. The third organic emitters have the property that, on emission of light, a transition from a portion of a ligand of one of the molecules to another portion thereof or another ligand takes place, which is referred to as intra-ligand charge transfer (ILCT) and which leads to a small singlet-triplet splitting of the molecule.

The third organic emitter is, for example, a transition metal complex having a central metal ion of the third transition metal period as emitter. The strong spin-orbit coupling induced by the central metal ion leads to relaxation of the degree to which the transition from a singlet state to a triplet state is forbidden. The third emitter having the small singlet-triplet splitting contributes to the ability to implement a CRI greater than 90 in a simple and inexpensive manner with high efficiency. The singlet-triplet splitting is the energy splitting between the lowest excited singlet state and the lowest excited triplet state. More particularly, white light emission is possible with high efficiency and simultaneously a very high CRI. An OLED based on this concept is producible in a simple and inexpensive manner, for example in an inline process. In addition, only three different emitters are required. This saves material and production time. In addition, in such thin components, less efficiency-reducing organic modes are induced, and so high-efficiency, inexpensive OLEDs can be implemented with simultaneously high light quality. For example, it is possible to dispense with the use of a plurality of OLEDs stacked one on top of another and thus to enable a very simple OLED structure. Optionally, a covering body may be formed above the second electrode.

The particularly high CRI is implemented, for example, by virtue of the third emitter being an emitter that phosphoresces in the red spectral region. For example, the third emitter is an emitter that phosphoresces in the deep red spectral region. The third emitter exhibits, for example, at room temperature, both a deep red emission from the triplet state and a higher-energy emission band which results from the thermally activated population of a higher-lying singlet state. This behaviour can be caused, for example, by the small singlet-triplet splitting. The small singlet-triplet splitting can be achieved, for example, by using, as the third emitter, emitters having high intra-ligand charge transfer (ILCT) character in their lowest electronic states.

Examples of these are the compounds shown in FIG. 4 and FIG. 5. These compounds are triplet emitters which have an additional high-energy emission band which results from a singlet state which is thermally populated even at room temperature. If the compounds mentioned or comparable compounds having sufficiently low-energy triplet emission and emitting states with ILCT character are used in the co-doped red-green unit of the OLED, the triplet emission very adequately covers the red spectral region, which leads to high R₈ and R₉ values. The spectral “gap” between the green and red emission which arises when a conventional emitter having an identical emission maximum is used is filled by the thermally activated singlet emission of the third organic emitters, and so the CRI is increased significantly.

In particular embodiments, the third organic emitters which emit in the red spectral region are compounds selected from the formulae (I), (Ia) and (II):

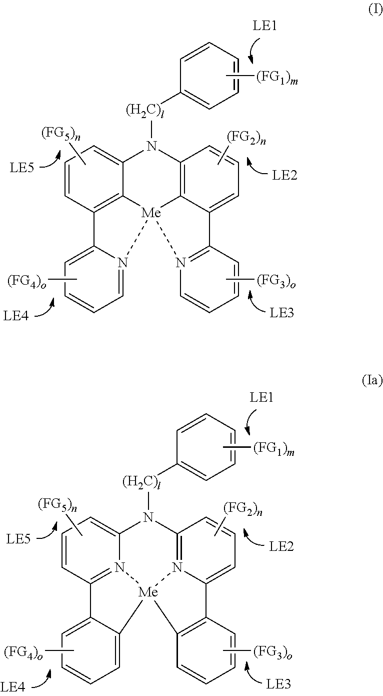

In the compounds of the formulae (I) and (Ia), Me is a transition metal, preferably selected from the group consisting of Re, Ru, Os, Co, Rh, Ir, Pd, Pt, Cu, Ag and Au; each FG₁ to FG₅ group is independently selected from the group consisting of linear or branched C1-C12 alkyl, C2-C12 alkenyl, C2-C12 alkynyl, C3-C8 cycloalkyl, C6-C14 aryl, 5-14-membered heteroaryl in which 1 to 4 ring atoms are independently nitrogen, oxygen or sulphur, 5-14-membered heteroalicyclyl in which 1 to 4 ring atoms are independently nitrogen, oxygen or sulphur, alkylaryl, arylalkyl, alkylheteroaryl, heteroarylalkyl, —Cl, —F, —Br, —I, —CN, C(halogen)₃, —NO₂, —OR, —C(O)R, —C(O)OR, —OC(O)R, —C(O)NRR′, —NRR′, —N⁺RR′R″, —NR—C(O)R′, —NR—C(O)OR′, —NR—S(O)₂R′, —SR, —S(O)R, —S(O)₂R, —S(O)₂OR, —S(O)₂NRR′, —SC(O)R, —C(S)R, —OC(S)R, —C(S)—NRR′, —NR—C(O)—NR′R″, —PO₃RR′ and —SiRR′R″; or two adjacent FG₁, FG₂, FG₃, FG₄, FG₅ groups in each case, together with the carbon atoms to which they are bonded, form a substituted or unsubstituted cyclic group which is selected from the group consisting of C3-C8 cycloalkyl, C6-C14 aryl, 5-14-membered heteroaryl in which 1 to 4 ring atoms are independently nitrogen, oxygen or sulphur, 5-14-membered heteroalicyclyl in which 1 to 4 ring atoms are independently nitrogen, oxygen or sulphur, where, if the group is substituted, the substituent(s) is/are selected from linear or branched C1-12 alkyl, C2-C12 alkenyl, C2-C12 alkynyl, C3-C8 cycloalkyl, C6-C14 aryl, 5-14-membered heteroaryl in which 1 to 4 ring atoms are independently nitrogen, oxygen or sulphur, 5-14-membered heteroalicyclyl in which 1 to 4 ring atoms are independently nitrogen, oxygen or sulphur, alkylaryl, arylalkyl, heteroarylalkyl and alkylheteroaryl; each R, R′ and R″ is independently selected from the group consisting of hydrogen, linear or branched C1-12 alkyl, C2-C12 alkenyl, C2-C12 alkynyl, C3-C8 cycloalkyl, C6-C14 aryl, 5-14-membered heteroaryl in which 1 to 4 ring atoms are independently nitrogen, oxygen or sulphur, 5-14-membered heteroalicyclyl in which 1 to 4 ring atoms are independently nitrogen, oxygen or sulphur, alkylaryl, arylalkyl, heteroarylalkyl and alkylheteroaryl, or R and R′, if they are bonded to a common nitrogen atom, together with the nitrogen atom form an unsubstituted cyclic group which is selected from the group consisting of 5-14-membered heteroaryl in which 1 to 4 ring atoms are independently nitrogen, oxygen or sulphur and 5-14-membered heteroalicyclyl in which 1 to 4 ring atoms are independently nitrogen, oxygen or sulphur;

“l” is 0, 1 or 2;

“m” is an integer from 0 to 5;

each “n” is an integer from 0 to 3; and

each “o” is an integer from 0 to 4.

In the compounds of the formula (II), Me is a transition metal, preferably selected from the group consisting of Re, Ru, Os, Co, Rh, Ir, Pd, Pt, Cu, Ag and Au;

“X” is C-FG₆, C—H or N;

each FG₆, FG₇, FG₈ group is independently selected from the group consisting of linear or branched C1-C12 alkyl, C2-C12 alkenyl, C2-C12 alkynyl, C3-C8 cycloalkyl, C6-C14 aryl, 5-14-membered heteroaryl in which 1 to 4 ring atoms are independently nitrogen, oxygen or sulphur, 5-14-membered heteroalicyclyl in which 1 to 4 ring atoms are independently nitrogen, oxygen or sulphur, alkylaryl, arylalkyl, alkylheteroaryl, heteroarylalkyl, —Cl, —F, —Br, —I, —CN, C(halogen)₃, —NO₂, —OR, C(O)R, C(O)OR, —OC(O)R, —C(O)NRR′, —NRR′, —N⁺RR′R″, —NR—C(O)R′, —NR—C(O)OR′, —NR—S(O)₂R′, —SR, —S(O)R, —S(O)₂R, —S(O)₂OR, —S(O)₂NRR′, —SC(O)R, —C(S)R, —OC(S)R, —C(S)—NRR′, —NR—C(O)—NR′R″, —PO₃RR′ and —SiRR′R″ or two adjacent FG₆, FG₇, FG₈ groups in each case, together with the carbon atoms to which they are bonded, form a substituted or unsubstituted cyclic group which is selected from the group consisting of C3-C8 cycloalkyl, C6-C14 aryl, 5-14-membered heteroaryl in which 1 to 4 ring atoms are independently nitrogen, oxygen or sulphur, 5-14-membered heteroalicyclyl in which 1 to 4 ring atoms are independently nitrogen, oxygen or sulphur, where, if the group is substituted, the substituent(s) is/are selected from linear or branched C1-12 alkyl, C2-C12 alkenyl, C2-C12 alkynyl, C3-C8 cycloalkyl, C6-C14 aryl, 5-14-membered heteroaryl in which 1 to 4 ring atoms are independently nitrogen, oxygen or sulphur, 5-14-membered heteroalicyclyl in which 1 to 4 ring atoms are independently nitrogen, oxygen or sulphur, alkylaryl, arylalkyl, heteroarylalkyl and alkylheteroaryl; each R, R′ and R″ is independently selected from the group consisting of hydrogen, linear or branched C1-12 alkyl, C2-C12 alkenyl, C2-C12 alkynyl, C3-C8 cycloalkyl, C6-C14 aryl, 5-14-membered heteroaryl in which 1 to 4 ring atoms are independently nitrogen, oxygen or sulphur, 5-14-membered heteroalicyclyl in which 1 to 4 ring atoms are independently nitrogen, oxygen or sulphur, alkylaryl, arylalkyl, heteroarylalkyl and alkylheteroaryl, or R and R′, if they are bonded to a common nitrogen atom, together with the nitrogen atom form an unsubstituted cyclic group which is selected from the group consisting of 5-14-membered heteroaryl in which 1 to 4 ring atoms are independently nitrogen, oxygen or sulphur and 5-14-membered heteroalicyclyl in which 1 to 4 ring atoms are independently nitrogen, oxygen or sulphur;

“p” is an integer from 0 to 3; and

each “q” is independently an integer from 0 to 4.

It is the explicit intention that all further embodiments which are disclosed hereinafter can also relate to the specific embodiments in which the third organic emitter that emits in the red spectral region is selected from compounds of the formulae (I), (Ia) and (II), as already defined.

In various embodiments, the singlet-triplet splitting of the third organic emitter is within a range between 0.05 eV and 0.3 eV.

In various embodiments, the singlet-triplet splitting of the third organic emitter is within a range between 0.1 eV and 0.2 eV.

In various embodiments, the singlet-triplet splitting of the third organic emitter is about 0.25 eV.

In various embodiments, one of the ligands of the metal atom of the third organic emitter has at least one aromatic group and optionally at least one functional group bonded thereto.

In various embodiments, the functional group is selected from an alkyl group, an aromatic group and a halogen group.

In various embodiments, the alkyl group is methyl, ethyl, propyl, butyl, isopropyl or tert-butyl.

In various embodiments, the aromatic group is phenyl, pyridine, pyrrole, thienyl, mono-, di-, tri- or tetrazole, mono-, di-, tri- or tetrazine or oxazole.

In various embodiments, the halogen group is fluorine, chlorine, bromine or iodine.

In various embodiments, the organic functional layer structure has a first emitter layer including at least one of the organic emitters, a second emitter layer including at least one of the organic emitters, and/or a third emitter layer including at least one of the organic emitters.

In various embodiments, a first interlayer is formed between the first emitter layer and the second emitter layer. Alternatively or additionally, a second interlayer is formed between the second emitter layer and the third emitter layer.

The first interlayer may, for example, be a first intermediate electrode or a first charge carrier generation layer structure (CGL). The second interlayer may, for example, be a second intermediate electrode or a second charge carrier generation layer structure (CGL).

In various embodiments, the emitter layers include one of the organic emitters. For example, the emitter layers each include exactly one emitter, i.e. exactly one kind of organic emitter, for example either the first organic emitter or the second organic emitter or the third organic emitter. For example, the first emitter layer includes the first organic emitter, the second emitter layer the second organic emitter, and the third emitter layer the third organic emitter. The emitter layers may have a stacked configuration one on top of another in any sequence.

In various embodiments, at least one of the emitter layers includes two of the organic emitters. For example, the first or second emitter layer includes two of the organic emitters. For example, the first emitter layer includes the first organic emitter and the second emitter layer includes the second organic emitter and the third organic emitter. Alternatively, the first emitter layer includes the first organic emitter and the second organic emitter, and the second emitter layer includes the third organic emitter. Alternatively, the first emitter layer includes the first organic emitter and the third organic emitter, and the second emitter layer includes the second organic emitter. In these cases, it is optionally possible to dispense with the third emitter layer. In addition, the first emitter layer may be formed above or below the second emitter layer. One advantage of this OLED is that the organic functional layer structure is producible with a low thickness overall, since only two separate emitter layers can be used.

In various embodiments, at least one of the emitter layers includes three of the organic emitters. For example, the first emitter layer includes the first, second and third organic emitters. In this case, it is optionally possible to dispense with the second and/or third emitter layer. One advantage of this OLED is that the organic functional layer structure is producible with a low thickness, since only one emitter layer can be used.

For production of a white spectrum, it is possible for the emitter layer including the first organic emitters that emit in the blue to be formed directly on the emitter layer including the third organic emitters or for the emitter layer including the first organic emitters that emit in the blue to be formed as a separate unit above or below the emitter layer including the third organic emitters. The second organic emitter that emits in the green spectral region and the third organic emitter that emits in the red spectral region may be disposed in the same or different layers of the corresponding emitter layer. The second organic emitter that emits in the green spectral region and/or the third organic emitter that emits in the red spectral region may each be present as individual emitter layers or be doped in one or two emitter layers.

In various embodiments, the organic light emitting component emits white light.

### BRIEF DESCRIPTION OF THE DRAWINGS

The invention is explained in greater detail below on the basis of an exemplary embodiment, wherein also as before no distinction will be drawn specifically among the claim categories and the features in the context of the independent claims are intended also to be disclosed in other combinations. In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIG. 1 shows the emission spectrum of a conventional white organic light-emitting component and the spectral colour rendering values of the eight standard chromaticity diagrams;

FIG. 2 shows a table of several colour rendering indices of the spectrum shown in FIG. 1 for a conventional organic light-emitting component;

FIG. 3 shows a section diagram of a working example of a layer structure of an organic light-emitting component;

FIG. 4 shows a working example of an organic emitter having a small singlet-triplet splitting;

FIG. 5 shows a working example of an organic emitter having a small singlet-triplet splitting;

FIG. 6 shows a section diagram of a working example of a layer structure of an organic light-emitting component;

FIG. 7 shows a section diagram of a working example of a layer structure of an organic light-emitting component;

FIG. 8A shows working examples of organic emitters;

FIG. 8B shows working examples of organic emitters;

FIG. 9A shows working examples of organic emitters;

FIG. 9B shows working examples of organic emitters;

FIG. 9C shows working examples of organic emitters;

FIG. 9D shows working examples of organic emitters;

FIG. 9E shows working examples of organic emitters; and

FIG. 9F shows working examples of organic emitters.

### DETAILED DESCRIPTION

In the detailed description which follows, reference is made to the appended drawings, which form part of this description and in which, for illustration, specific working examples in which the invention can be executed are shown. In this regard, directional terminology, for instance “top”, “bottom”, “front”, “back”, “foremost”, “rearmost”, etc. is used with reference to the orientation of the figure(s) described. Since components of working examples can be positioned in a number of different orientations, the directional terminology serves for illustration and is not restrictive in any way at all. It will be apparent that other working examples can be utilized and structural or logical alterations can be undertaken without departing from the scope of protection of the present invention. It will be apparent that the features of the various working examples described herein can be combined with one another, unless specifically stated otherwise. The detailed description which follows should therefore not be interpreted in a restrictive manner, and the scope of protection of the present invention is defined by the appended claims.

In the context of this description, the terms “connected”, “attached” and “coupled” are used to describe either a direct or an indirect connection, a direct or an indirect attachment and a direct or an indirect coupling. In the figures, identical or similar elements are given identical reference numerals, where appropriate.

An organic light-emitting component may be configured, in various working examples, as an organic light emitting diode (OLED) or as an organic light-emitting transistor. The organic light-emitting component may, in various working examples, be part of an integrated circuit. In addition, a multitude of organic light-emitting components may be provided, accommodated, for example, in a common housing.

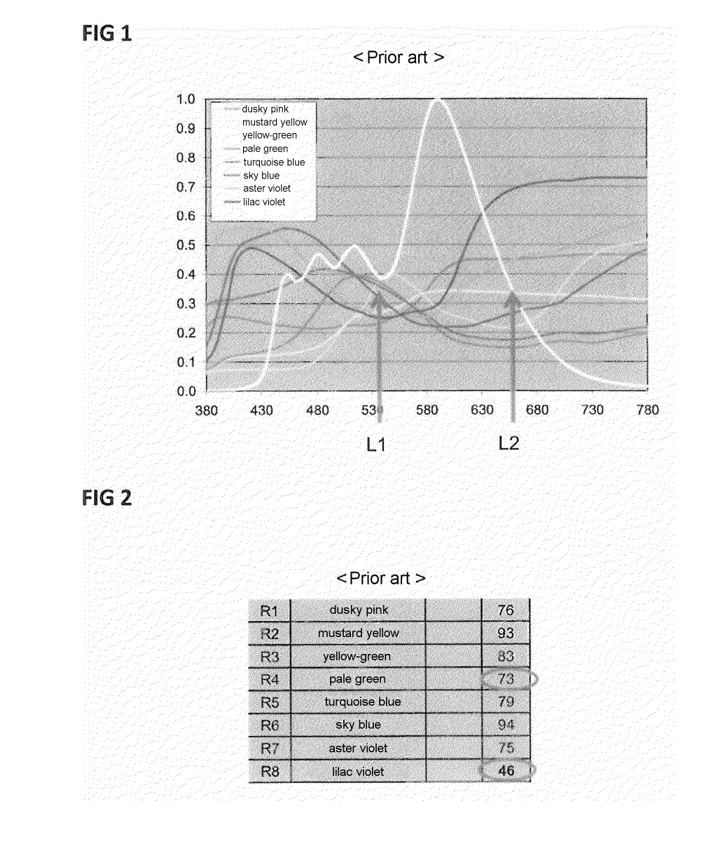

FIG. 1 shows an emission spectrum of a conventional organic light-emitting component and the spectral colour rendering values of the eight standard chromaticity diagrams. The conventional organic light-emitting component emits white light. In other words, the organic light-emitting component emits in the white spectral region or in the white. In FIG. 1, the white line represents the emission spectrum emitted by the OLED. The other curves represent the reflectivities of the test colours when the test colours are illuminated with a standard light source, for example a black body radiator.

The conventional organic light-emitting component includes a plurality of emitters, for example emitters which emit in the blue, emitters which emit in the green and emitters which emit in the red. The emitters which emit in the green and/or red may be disposed, for example, in a first light-emitting layer structure and may together emit yellow light through colour mixing. The emitters which emit in the green and/or red may be disposed, for example, in the same layer or in different layers of the first light-emitting layer structure. The emitters which emit in the blue may be disposed in a second light-emitting layer structure. The yellow light from the first light-emitting layer structure and the blue light from the second light-emitting layer structure mix to give the white light of the conventional organic light-emitting component.

The emitter which emits in the red is a conventional triplet emitter which does not exhibit any thermally activated singlet emission.

The colour rendering diagram gives the reflectivity over the wavelength of the light generated by the organic light-emitting component for the test colours dusky pink R₁, mustard yellow R₂, yellow-green R₃, light green R₄, turquoise blue R₅, sky blue R₆, aster violet R₇ and lilac violet R₈.

The white light of the conventional organic light-emitting component has a first spectral gap L1, i.e. a local minimum in the green spectral region, for example at about 540 nm, and declines in the deep red spectral regions, for example in the range greater than 650 nm, which can be referred to as a second spectral gap L2. If an attempt is made to close the first spectral gap L1 with a conventional emitter that emits in the light red spectral region, for example with an emission maximum less than 590 nm, the second spectral gap L2 increases in size. If an attempt is made to close the second spectral gap L2 with a conventional emitter that emits in the deep red spectral region, for example with an emission maximum greater than 630 nm, the first spectral gap L1 increases in size.

FIG. 2 shows a table of several colour rendering indices of the spectrum shown in FIG. 1 for a conventional organic light-emitting component, for example the conventional organic light-emitting component elucidated above. In the table, the colour rendering values are assigned to the corresponding colours and their colour rendering indices. More particularly, the colour rendering values of the colours of dusky pink to lilac violet having the colour rendering indices R₁ to R₈ are assigned to said colours. Not entered in the table is the colour rendering value R₉ for saturated red.

Noticeably low values are the colour rendering value of 73 for the light green colour R₄, and the colour rendering value of 46 for the lilac violet colour R₈. These low colour rendering values correspond to the drops in the green and deep red spectral region that are shown in the emission spectrum according to FIG. 1. A CRI greater than 90 is not possible with these low colour rendering values.

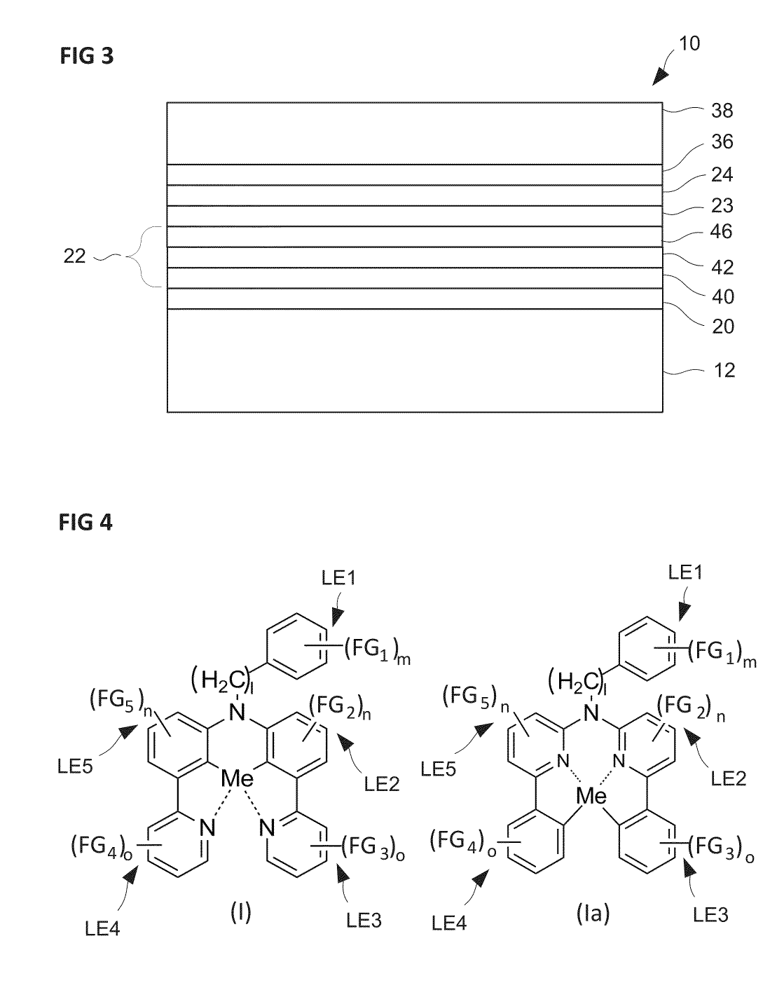

FIG. 3 shows a detailed section view of a layer structure of a working example of an organic light-emitting component 10. The organic light-emitting component 10 may be configured as a top emitter and/or bottom emitter. If the organic light-emitting component 10 is configured as a top emitter and bottom emitter, the organic light-emitting component 10 may be referred to as an optically transparent component, for example a transparent organic light-emitting diode. The organic light-emitting component 10 may be configured as a stacked OLED.

The organic light emitting component 10 has a carrier 12 and an active region above the carrier 12. A first barrier layer (not shown), for example a first thin barrier layer, may be formed between the carrier 12 and the active region. The active region has a first electrode 20, an organic functional layer and a second electrode 23. The first electrode 20 is formed above the carrier 12. The organic functional layer structure 22 is formed above the first electrode 20. The second electrode 23 is formed above the organic functional layer structure 22. An encapsulation layer 24 is formed above the active region. The encapsulation layer 24 may be configured as a second barrier layer, for example as a second thin barrier layer. Above the active region and optionally above the encapsulation layer 24 is disposed a cover body 38. The cover body 38 may be disposed on the encapsulation layer 24, for example, by means of a bonding layer 36.

The active region is an electrically and/or optically active region. The active region is, for example, the region of the organic light-emitting component 10 in which electrical current flows for operation of the organic light emitting component 10 and/or in which electromagnetic radiation, especially light, is generated or absorbed.

The carrier 12 may have a translucent or transparent configuration. The carrier 12 serves as carrier element for electronic elements or layers, for example light-emitting elements. The carrier 12 may include or be formed from, for example, glass, quartz and/or a semiconductor material or any other suitable material. In addition, the carrier 12 may include or be formed from a polymer film or a laminate including one or more polymer films. The polymer may include one or more polyolefins. In addition, the polymer may include polyvinyl chloride (PVC), polystyrene (PS), polyester and/or polycarbonate (PC), polyethylene terephthalate (PET), polyether sulphone (PES) and/or polyethylene naphthalate (PEN). The carrier 12 may include or be formed from a metal, for example copper, silver, gold, platinum, iron, for example a metal alloy, for example steel. The carrier 12 may take the form of a metal foil or metal-coated film. The carrier 12 may be part of or form a mirror structure. The carrier 12 may have a mechanically rigid region and/or a mechanically flexible region and/or be configured so as to be flexible at least in some regions.

The first electrode 20 may be configured as anode or as cathode. The first electrode 20 may have a translucent or transparent configuration. The first electrode 20 includes an electrically conductive material, for example metal and/or a transparent conductive oxide (TCO), or a layer stack of several layers including metals or TCOs. The first electrode 20 may, for example, include a layer stack of a combination of a layer of a metal on a layer of a TCO, or vice versa. One example is a silver layer applied to an indium tin oxide (ITO) layer (Ag on ITO), or ITO-Ag-ITO multilayers.

The metal used may, for example, be Ag, Pt, Au, Mg, Al, Ba, In, Ca, Sm or Li, and compounds, combinations or alloys of these materials.

In various embodiments, the metal is not platinum.

Transparent conductive oxides are transparent conductive materials, for example metal oxides, for example zinc oxide, tin oxide, cadmium oxide, titanium oxide, indium oxide or indium tin oxide (ITO). As well as binary metal-oxygen compounds, for example ZnO, SnO2, or In2O3, the group of the TCOs also includes ternary metal-oxygen compounds, for example AlZnO, Zn2SnO4, CdSnO3, ZnSnO3, MgIn2O4, GaInO3, Zn2In2O5 or In4Sn3O12, or mixtures of different transparent conductive oxides.

The first electrode 20 may, alternatively or additionally to the materials mentioned, include: networks composed of metallic nanowires and -particles, for example of Ag, networks composed of carbon nanotubes, graphene particles and graphene layers, and/or networks composed of semiconductive nanowires. For example, the first electrode 20 may include or be formed from one of the following structures: a network composed of metallic nanowires, for example of Ag, combined with conductive polymers, a network composed of carbon nanotubes combined with conductive polymers, and/or graphene layers and composites. In addition, the first electrode 20 may include electrically conductive polymers or transition metal oxides.

The first electrode 20 may have, for example, a layer thickness within a range from 10 nm to 500 nm, for example from less than 25 nm to 250 nm, for example from 50 nm to 100 nm.

The first electrode 20 may have a first electrical connection to which a first electrical potential can be applied. The first electrical potential can be provided by an energy source (not shown), for example by a current source or a voltage source. Alternatively, the first electrical potential can be applied to the carrier 12 and supplied indirectly to the first electrode 20 via the carrier 12. The first electrical potential may, for example, be the earth potential or another defined reference potential.

The organic functional layer structure 22 may include a hole injection layer 40, a hole transport layer, a first emitter layer 42, an electron transport layer and/or an electron injection layer 46.

The hole injection layer 40 may be formed atop or above the first electrode 20. The hole injection layer 40 may include or be formed from one or more of the following materials: HAT-CN, Cu(I)pFBz, MoOx, WOx, VOx, ReOx, F4-TCNQ, NDP-2, NDP-9, Bi(III)pFBz, F16CuPc; NPB (N,N′-bis(naphthalen-1-yl)-N,N′-bis(phenyl)benzidine); beta-NPB (N,N′-bis(naphthalen-2-yl)-N,N′-bis(phenyl)benzidine); TPD (N,N′-bis(3-methylphenyl)-N,N′-bis(phenyl)benzidine); spiro-TPD (N,N′-bis(3-methylphenyl)-N,N′-bis(phenyl)benzidine); spiro-NPB (N,N′-bis(naphthalen-1-yl)-N,N′-bis(phenyl)spiro); DMFL-TPD (N,N′-bis(3-methylphenyl)-N,N′-bis(phenyl)-9,9-dimethylfluorene); DMFL-NPB (N,N′-bis(naphthalen-1-yl)-N,N′-bis(phenyl)-9,9-dimethylfluorene); DPFL-TPD (N,N′-bis(3-methylphenyl)-N,N′-bis(phenyl)-9,9-diphenylfluorene); DPFL-NPB (N,N′-bis(naphthalen-1-yl)-N,N′-bis(phenyl)-9,9-diphenylfluorene); spiro-TAD (2,2′,7,7′-tetrakis(N,N-diphenylamino)-9,9′-spirobifluorene); 9,9-bis[4-(N,N-bis(biphenyl-4-yl)amino)phenyl]-9H-fluorene; 9,9-bis[4-(N,N-bis(naphthalen-2-yl)amino)phenyl]-9H-fluorene; 9,9-bis[4-(N,N′-bis(naphthalen-2-yl)-N,N′-bisphenylamino)phenyl]-9H-fluorene; N,N′-bis(phenanthren-9-yl)-N,N′-bis(phenyl)benzidine; 2,7-bis[N,N-bis(9,9-spirobifluoren-2-yl)amino]-9,9-spirobifluorene; 2,2′-bis[N,N-bis(biphenyl-4-yl)amino]-9,9-spirobifluorene; 2,2′-bis(N,N-diphenylamino)-9,9-spirobifluorene; di[4-(N,N-ditolylamino)phenyl]cyclohexane; 2,2′,7,7′-tetra(N,N-ditolyl)aminospirobifluorene; and/or N,N,N′,N′-tetra(naphthalen-2-yl)benzidine.

The hole injection layer 40 may have a layer thickness within a range from about 10 nm to about 1000 nm, for example within a range from about 30 nm to about 300 nm, for example within a range from about 50 nm to about 200 nm.

The hole transport layer may be formed atop or above the hole injection layer 40. The hole transport layer may include or be formed from one or more of the following materials: NPB (N,N′-bis(naphthalen-1-yl)-N,N′-bis(phenyl)benzidine); beta-NPB (N,N′-bis(naphthalen-2-yl)-N,N′-bis(phenyl)benzidine); TPD (N,N′-bis(3-methylphenyl)-N,N′-bis(phenyl)benzidine); spiro-TPD (N,N′-bis(3-methylphenyl)-N,N′-bis(phenyl)benzidine); spiro-NPB (N,N′-bis(naphthalen-1-yl)-N,N′-bis(phenyl)spiro); DMFL-TPD (N,N′-bis(3-methylphenyl)-N,N′-bis(phenyl)-9,9-dimethylfluorene); DMFL-NPB (N,N′-bis(naphthalen-1-yl)-N,N′-bis(phenyl)-9,9-dimethylfluorene); DPFL-TPD (N,N′-bis(3-methylphenyl)-N,N′-bis(phenyl)-9,9-diphenylfluorene); DPFL-NPB (N,N′-bis(naphthalen-1-yl)-N,N′-bis(phenyl)-9,9-diphenylfluorene); spiro-TAD (2,2′,7,7′-tetrakis(N,N-diphenylamino)-9,9′-spirobifluorene); 9,9-bis[4-(N,N-bis(biphenyl-4-yl)amino)phenyl]-9H-fluorene; 9,9-bis[4-(N,N-bis(naphthalen-2-yl)amino)phenyl]-9H-fluorene; 9,9-bis[4-(N,N′-bis(naphthalen-2-yl)-N,N′-bisphenylamino)phenyl]-9H-fluorene; N,N′-bis(phenanthren-9-yl)-N,N′-bis(phenyl)benzidine; 2,7-bis[N,N-bis(9,9-spirobifluoren-2-yl)amino]-9,9-spirobifluorene; 2,2′-bis[N,N-bis(biphenyl-4-yl)amino]-9,9-spirobifluorene; 2,2′-bis(N,N-diphenylamino)-9,9-spirobifluorene; di[4-(N,N-ditolylamino)phenyl]cyclohexane; 2,2′,7,7′-tetra(N,N-ditolyl)aminospirobifluorene; and N,N,N′,N′-tetra(naphthalen-2-yl)benzidine.

The hole transport layer may have a layer thickness within a range from about 5 nm to about 50 nm, for example within a range from about 10 nm to about 30 nm, for example about 20 nm.

The first emitter layer 42 is formed atop or above the hole transport layer. The first emitter layer 42 includes fluorescent and/or phosphorescent emitters. The first emitter layer 42 includes first emitters which emit in the blue, second emitters which emit in the green, and third emitters which exhibit deep red triplet emission and a higher-energy thermally activated singlet emission. The blue, green and red light of the first emitter layer 42 mixes to give white light. In the operation of the organic light-emitting component 10, the first emitter layer 42 thus emits white light. Molecules present as third emitters are as elucidated, for example, with reference to FIGS. 4, 5 and/or 10A, 10B and/or 11A to 11F.

The first emitter layer 42 may include organic polymers, organic oligomers, organic monomers, organic small non-polymeric molecules (“small molecules”) or a combination of these materials. The first emitter layer 42 may include or be formed from one or more of the following materials: organic or organometallic compounds such as derivatives of polyfluorene, polythiophene and polyphenylene (e.g. 2- or 2,5-substituted poly-p-phenylenevinylene) and metal complexes, for example iridium complexes such as green-phosphorescing Ir(ppy)3 (tris(2-phenylpyridine)iridium(III)) and/or such as blue-phosphorescing FIrPic (bis(3,5-difluoro-2-(2-pyridyl)phenyl-(2-carboxypyridyl)iridium(III)) and/or blue-fluorescing DPAVBi (4,4-bis[4-(di-p-tolylamino)styryl]biphenyl). Such non-polymeric emitters can be deposited, for example, by means of thermal evaporation. The first organic emitter used may, for example, be SEB-097 or BD314. In addition, it is possible to use polymer emitters which can be deposited, for example, by means of a wet-chemical process, for example a spin-coating process. The emitters may suitably be embedded in a matrix material, for example an organic material or a polymer, for example an epoxide.

The first emitter layer 42 may have a layer thickness within a range from about 5 nm to about 50 nm, for example within a range from about 10 nm to about 30 nm, for example about 20 nm.

The electron transport layer may be formed, for example deposited, atop or above the first emitter layer 42. The electron transport layer may include or be formed from one or more of the following materials: NET-18; 2,2′,2″-(1,3,5-benzenetriyl)-tris(1-phenyl-1H-benzimidazole); 2-(4-biphenylyl)-5-(4-tert-butylphenyl)-1,3,4-oxadiazole, 2,9-dimethyl-4,7-diphenyl-1,10-phenanthroline (BCP); 8-hydroxyquinolinolatolithium, 4-(naphthalen-1-yl)-3,5-diphenyl-4H-1,2,4-triazole; 1,3-bis[2-(2,2′-bipyridin-6-yl)-1,3,4-oxadiazol-5-yl]benzene; 4,7-diphenyl-1,10-phenanthroline (BPhen); 3-(4-biphenylyl)-4-phenyl-5-tert-butylphenyl-1,2,4-triazole; bis(2-methyl-8-quinolinolato)-4-(phenylphenolato)aluminium; 6,6′-bis[5-(biphenyl-4-yl)-1,3,4-oxadiazol-2-yl]-2,2′-bipyridyl; 2-phenyl-9,10-di(naphthalen-2-yl)anthracene; 2,7-bis[2-(2,2′-bipyridin-6-yl)-1,3,4-oxadiazol-5-yl]-9,9-dimethylfluorene; 1,3-bis[2-(4-tert-butylphenyl)-1,3,4-oxadiazol-5-yl]benzene; 2-(naphthalen-2-yl)-4,7-diphenyl-1,10-phenanthroline; 2, 9-bis(naphthalen-2-yl)-4,7-diphenyl-1,10-phenanthroline; tris(2,4,6-trimethyl-3-(pyridin-3-yl)phenyl)borane; 1-methyl-2-(4-(naphthalen-2-yl)phenyl)-1H-imidazo[4,5-f][1,10]phenanthroline; phenyldipyrenylphosphine oxide; naphthalenetetracarboxylic dianhydride or the imides thereof; perylenetetracarboxylic dianhydride or the imides thereof; and substances based on siloles with a silacyclopentadiene unit.

The electron transport layer may have a layer thickness within a range from about 5 nm to about 50 nm, for example within a range from about 10 nm to about 30 nm, for example about 20 nm.

The electron injection layer 46 may be formed atop or above the electron transport layer. The electron injection layer 46 may include or be formed from one or more of the following materials: NDN-26, MgAg, Cs2CO3, Cs3PO4, Na, Ca, K, Mg, Cs, Li, LiF; 2,2′,2″-(1,3,5-benzenetriyl)-tris(1-phenyl-1H-benzimidazole); 2-(4-biphenylyl)-5-(4-tert-butylphenyl)-1,3,4-oxadiazole, 2,9-dimethyl-4,7-diphenyl-1,10-phenanthroline (BCP); 8-hydroxyquinolinolatolithium, 4-(naphthalen-1-yl)-3,5-diphenyl-4H-1,2,4-triazole; 1,3-bis[2-(2,2′-bipyridin-6-yl)-1,3,4-oxadiazol-5-yl]benzene; 4,7-diphenyl-1,10-phenanthroline (BPhen); 3-(4-biphenylyl)-4-phenyl-5-tert-butylphenyl-1,2,4-triazole; bis(2-methyl-8-quinolinolato)-4-(phenylphenolato)aluminium; 6,6′-bis[5-(biphenyl-4-yl)-1,3,4-oxadiazol-2-yl]-2,2′-bipyridyl; 2-phenyl-9,10-di(naphthalen-2-yl)anthracene; 2,7-bis[2-(2,2′-bipyridin-6-yl)-1,3,4-oxadiazol-5-yl]-9,9-dimethylfluorene; 1,3-bis[2-(4-tert-butylphenyl)-1,3,4-oxadiazol-5-yl]benzene; 2-(naphthalen-2-yl)-4,7-diphenyl-1,10-phenanthroline; 2,9-bis(naphthalen-2-yl)-4,7-diphenyl-1,10-phenanthroline; tris(2,4,6-trimethyl-3-(pyridin-3-yl)phenyl)borane; 1-methyl-2-(4-(naphthalen-2-yl)phenyl)-1H-imidazo[4,5-f][1,10]phenanthroline; phenyldipyrenylphosphine oxide; naphthalenetetracarboxylic dianhydride or the imides thereof; perylenetetracarboxylic dianhydride or the imides thereof; and substances based on siloles with a silacyclopentadiene unit.

The electron injection layer 46 may have a layer thickness within a range from about 5 nm to about 200 nm, for example within a range from about 20 nm to about 50 nm, for example about 30 nm.

The organic functional layer structure 22 may have, for example, a layer thickness of not more than about 3 μm, for example a layer thickness of not more than about 1 μm, for example a layer thickness of not more than about 300 nm.

The organic light-emitting component 10 may optionally include further functional layers, for example disposed atop or above the first emitter layer 42 or atop or above the electron transport layer. The further functional layers may, for example, be internal or external in-/out-coupling structures which can further improve the functionality and hence the efficiency of the organic light-emitting component 10.

The second electrode 23 may be formed in accordance with the configurations of the first electrode 20, where the first electrode 20 and the second electrode 23 may have identical or different configurations. The second electrode 23 may be configured as anode or as cathode. The second electrode 23 may have a second electrical connection to which a second electrical potential can be applied. The second electrical potential may be provided by the same energy source as the first electrical potential, or a different one. The second electrical potential may be different from the first electrical potential. The second electrical potential may have, for example, such a value that the difference from the first electrical potential has a value within a range from about 1.5 V to about 20 V, for example a value within a range from about 2.5 V to about 15 V, for example a value within a range from about 3 V to about 12 V.

The encapsulation layer 24 may also be referred to as thin-layer encapsulation. The encapsulation layer 24 may be configured as a translucent or transparent layer. The encapsulation layer 24 forms a barrier against chemical contaminants or atmospheric substances, especially against water (moisture) and oxygen. In other words, the encapsulation layer 24 is configured such that it can be penetrated only in very small proportions at most, if at all, by substances that can damage the organic light-emitting component 10, for example water, oxygen or solvents. The encapsulation layer 24 may be configured as a single layer, a layer stack or a layer structure.

The encapsulation layer 24 may include or be formed from: aluminium oxide, zinc oxide, zirconium oxide, titanium oxide, hafnium oxide, tantalum oxide, lanthanum oxide, silicon oxide, silicon nitride, silicon oxynitride, indium tin oxide, indium zinc oxide, aluminium-doped zinc oxide, poly(p-phenyleneterephthalamide), nylon-6,6, and mixtures and alloys thereof.

The encapsulation layer 24 may have a layer thickness of about 0.1 nm (one atom layer) to about 1000 nm, for example a layer thickness of about 10 nm to about 100 nm, for example 40 nm.

The encapsulation layer 24 may include a highly refractive material, for example one or more material(s) having a high refractive index, for example having a refractive index of at least 2.

If necessary, the first barrier layer on the carrier 12 may be formed so as to correspond to a configuration of the encapsulation layer 24.

The encapsulation layer 24 may be formed by means of a suitable deposition method, for example by means of an atomic layer deposition (ALD) method, for example a plasma-enhanced atomic layer deposition (PEALD) method or a plasma-less atomic layer deposition (PLALD) method, or by means of a chemical vapour deposition (CVD) method, for example a plasma-enhanced chemical vapour deposition (PECVD) method or a plasma-less chemical vapour deposition (PLCVD) method, or alternatively by means of other suitable deposition methods.

If necessary, an in- or out-coupling layer may be formed, for example, as an external film (not shown) on the carrier 12 or as an internal out-coupling layer (not shown) in the layer cross section of the organic light-emitting component 10. The in-/out-coupling layer may have a matrix and scattering sites distributed therein, the mean refractive index of the in-/out-coupling layer being greater than the mean refractive index of the layer from which the electromagnetic radiation is provided. Moreover, it is additionally possible to form one or more antireflection layers.

The bonding layer 36 may include, for example, adhesive and/or varnish, by means of which the cover body 38 is disposed, for example bonded, on the encapsulation layer 24. The bonding layer 36 may have a transparent or translucent configuration. The bonding layer 36 may include, for example, particles which scatter electromagnetic radiation, for example light-scattering particles. In this way, the bonding layer 36 can act as a scattering layer and can lead to an improvement in the colour angle distortion and the out-coupling efficiency.

Light-scattering particles provided may be dielectric scattering particles, for example of a metal oxide, for example silicon oxide (SiO2), zinc oxide (ZnO), zirconium oxide (ZrO2), indium tin oxide (ITO) or indium zinc oxide (IZO), gallium oxide (Ga2Ox), aluminium oxide or titanium oxide. Other particles may also be suitable, provided that they have a refractive index different from the effective refractive index of the matrix of the bonding layer 36, for example air bubbles, acrylate or hollow glass beads. In addition, for example, metallic nanoparticles, metals such as gold, silver or iron nanoparticles or the like may be provided as light-scattering particles.

The bonding layer 36 may have a layer thickness of greater than 1 μm, for example a layer thickness of several μm. In various working examples, the adhesive may be a lamination adhesive.

The bonding layer 36 may have a refractive index less than the refractive index of the cover body 38. The bonding layer 36 may include, for example, an adhesive of low refractive index, for example an acrylate having a refractive index of about 1.3. However, the bonding layer 36 may also include an adhesive of high refractive index, including, for example, non-scattering particles of high refractive index and a layer-thickness averaged refractive index corresponding roughly to the mean refractive index of the organic functional layer structure 22, for example within a range from about 1.7 to about 2.0.

What is called a getter layer or getter structure, i.e. a laterally structured getter layer (not shown), may be disposed atop or above the active region. The getter layer may have a translucent, transparent or opaque configuration. The getter layer may include or be formed from a material which absorbs and binds substances harmful to the active region. A getter layer may, for example, include or be formed from a zeolite derivative. The getter layer may have a layer thickness of greater than about 1 μm, for example a layer thickness of several μm. In various working examples, the getter layer may include a lamination adhesive or be embedded in the bonding layer 36.

The cover body 38 may be formed, for example, by a glass body, a metal foil or a sealed polymer film cover body. The cover body 38 may be formed, for example, by means of glass frit bonding, glass soldering or seal glass bonding by means of a conventional glass solder in the geometric edge regions of the organic light-emitting component 10 atop the encapsulation layer 24 or the active region. The cover body 38 may have, for example, a refractive index (for example at a wavelength of 633 nm) of 1.55.

FIG. 4 shows working examples of the third emitter of the organic light-emitting component 10, where the third emitter may be a compound of the formula I or Ia. The third organic emitter has a central metal ion and a ligand bonded to the metal ion at four coordination sites. The ligand has five ligand units LE1, LE2, LE3, LE4 and LE5. On emission of light, a charge transfer takes place in the third organic emitter from one of the ligand units LE1 to LE5 to another of the ligand units LE1 to LE5. In the third organic emitter, the singlet-triplet splitting is small. The fact that the singlet-triplet splitting is small means that the singlet-triplet splitting is, for example, within a range between 0.05 eV and 0.3 eV, for example between 0.1 eV and 0.2 eV, for example about 0.25 eV.

The third organic emitter is, for example, a transition metal complex having a central metal ion of the third transition metal period as emitter. The strong spin-orbit coupling induced by the central metal ion leads to relaxation of the degree to which the transition from a singlet state to a triplet state is forbidden.

The third organic emitter is an emitter which phosphoresces in the deep red spectral region and has an additional high-energy emission band which is a thermally activated singlet emission and which closes the first spectral gap L1 between the conventional emitter which emits in the green and the conventional emitter which emits in the red. The actual triplet emission of the third organic emitter extends over the long-wave deep red spectral region, in order to assure sufficient low-energy emission intensity here for good colour rendering, especially of the R₈ and R₉ values (saturated red).

The third organic emitter has platinum, for example, as the central metal ion. At least one of the ligand units LE1 to LE5 of the third organic emitter may have an aromatic ring and at least one FG₁, FG₂, FG₃, FG₄, FG₅ group. The FG₁, FG₂, FG₃, FG₄, FG₅ groups may be bonded to any position of the respective aromatic rings. The respective aromatic ring may have one or more of the FG₁, FG₂, FG₃, FG₄, FG₅ groups. Each of the FG₁, FG₂, FG₃, FG₄, FG₅ groups may, for example, be an alkyl group, an aromatic group or a halogen group. Suitable alkyl groups include, but are not restricted to, methyl, ethyl, propyl, butyl, isopropyl and tert-butyl. Suitable aromatic groups include, but are not restricted to, phenyl, pyridine, pyrrole, thienyl, mono-, di-, tri- or tetrazole, mono-, di-, tri- or tetrazine and oxazole. The halogen group includes, for example, fluorine, chlorine, bromine and iodine.

For example, an aromatic system, an alkyl, —CO—R′, —CS—R′, —NO₂, —N(alkyl)₃, N(aromatic)₃, —NH₃⁺, —CN, -halogen, —C(halogen)₃, —NH-alkyl, —NH-aromatic, —NHCO-alkyl, —NHCO-aromatic, —OCO-alkyl, —OCO-aromatic, —N(alkyl)₂, —N(aromatic)₂, —NH₂, —OH, —O—R′, —SCO-alkyl, —SCO-aromatic, —OCS—R′, —SH, —SO₃H, or —S—R′ may be bonded to the ligand units LE1 to LE5, where R′ may be hydrogen, alkyl, OH, O-alkyl, SH, S-alkyl, a halogen or an aromatic.

In various embodiments, as already described above, the third organic emitter is a compound of the formula (I) or (Ia) (see also FIG. 4):

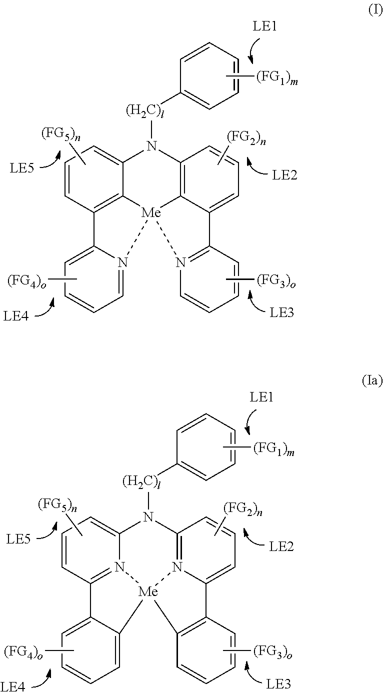

where:

Me is a transition metal, preferably selected from the group consisting of Re, Ru, Os, Co, Rh, Ir, Pd, Pt, Cu, Ag and Au; each FG₁ to FG₅ group is independently selected from the group consisting of linear or branched C1-C12 alkyl, C2-C12 alkenyl, C2-C12 alkynyl, C3-C8 cycloalkyl, C6-C14 aryl, 5-14-membered heteroaryl in which 1 to 4 ring atoms are independently nitrogen, oxygen or sulphur, 5-14-membered heteroalicyclyl in which 1 to 4 ring atoms are independently nitrogen, oxygen or sulphur, alkylaryl, arylalkyl, alkylheteroaryl, heteroarylalkyl, —Cl, —F, —Br, —I, —CN, C(halogen)₃, —NO₂, —OR, —C(O)R, —C(O)OR, —OC(O)R, —C(O)NRR′, —NRR′, —N⁺RR′R″, —NR—C(O)R′, —NR—C(O)OR′, —NR—S(O)₂R′, —SR, —S(O)R, —S(O)₂R, —S(O)₂OR, —S(O)₂NRR′, —SC(O)R, —C(S)R, —OC(S)R, —C(S)—NRR′, —NR—C(O)—NR′R″, —PO₃RR′ and —SiRR′R″; or

two adjacent FG₁, FG₂, FG₃, FG₄, FG₅ groups in each case, together with the carbon atoms to which they are bonded, form a substituted or unsubstituted cyclic group which is selected from the group consisting of C3-C8 cycloalkyl, C6-C14 aryl, 5-14-membered heteroaryl in which 1 to 4 ring atoms are independently nitrogen, oxygen or sulphur, 5-14-membered heteroalicyclyl in which 1 to 4 ring atoms are independently nitrogen, oxygen or sulphur, where, if the group is substituted, the substituent(s) is/are selected from linear or branched C1-12 alkyl, C2-C12 alkenyl, C2-C12 alkynyl, C3-C8 cycloalkyl, C6-C14 aryl, 5-14-membered heteroaryl in which 1 to 4 ring atoms are independently nitrogen, oxygen or sulphur, 5-14-membered heteroalicyclyl in which 1 to 4 ring atoms are independently nitrogen, oxygen or sulphur, alkylaryl, arylalkyl, heteroarylalkyl and alkylheteroaryl; each R, R′ and R″ is independently selected from the group consisting of hydrogen, linear or branched C1-12 alkyl, C2-C12 alkenyl, C2-C12 alkynyl, C3-C8 cycloalkyl, C6-C14 aryl, 5-14-membered heteroaryl in which 1 to 4 ring atoms are independently nitrogen, oxygen or sulphur, 5-14-membered heteroalicyclyl in which 1 to 4 ring atoms are independently nitrogen, oxygen or sulphur, alkylaryl, arylalkyl, heteroarylalkyl and alkylheteroaryl, or R and R′, if they are bonded to a common nitrogen atom, together with the nitrogen atom form an unsubstituted cyclic group which is selected from the group consisting of 5-14-membered heteroaryl in which 1 to 4 ring atoms are independently nitrogen, oxygen or sulphur and 5-14-membered heteroalicyclyl in which 1 to 4 ring atoms are independently nitrogen, oxygen or sulphur;

“l” is 0, 1 or 2;

“m” is an integer from 0 to 5;

each “n” is an integer from 0 to 3; and

each “o” is an integer from 0 to 4.

FIG. 5 shows a working example of the third organic emitter of the organic light-emitting component 10, where the third emitter may be a compound of the formula II. The third organic emitter has a central metal ion and at least one ligand. The ligand has, for example, three ligand units LE6, LE7 and LE8. On emission of light, a charge transfer takes place in the third organic emitter from one of the ligand units LE6, LE7 or LE8 to another of the ligand units LE6, LE7 or LE8. In the third organic emitter, the singlet-triplet splitting is small. The fact that the singlet-triplet splitting is small means that the singlet-triplet splitting is, for example, within a range between 0.05 eV and 0.3 eV, for example between 0.1 eV and 0.2 eV, for example about 0.25 eV.

The third organic emitter is an emitter which phosphoresces in the deep red spectral region and has an additional high-energy emission band which is a thermally activated singlet emission and which closes the first spectral gap L1 between the conventional emitter which emits in the green and the conventional emitter which emits in the red. The actual triplet emission of the third organic emitter extends over the long-wave deep red spectral region, in order to assure sufficient low-energy emission intensity here for good colour rendering, especially of the R₈ and R₉ values (saturated red).

The third organic emitter has platinum, for example, as the central metal ion. At least one of the ligand units LE6, LE7 or LE8 of the third organic emitter may have an aromatic ring and at least one FG₆, FG₇, FG₈ group. The FG₆, FG₇, FG₈ groups may be bonded at any position in the respective aromatic rings, including at more than one position. The FG₁, FG₂, FG₃, FG₄, FG₅ groups may be bonded at any position of the respective aromatic rings. Each aromatic ring may have one or more of the FG₁, FG₂, FG₃, FG₄, FG₅ groups. Each of the FG₁, FG₂, FG₃, FG₄, FG₅ groups may, for example, be an alkyl group, an aromatic group or a halogen group. Suitable alkyl groups include, but are not restricted to, methyl, ethyl, propyl, butyl, isopropyl and tert-butyl. Suitable aromatic groups include, but are not restricted to, phenyl, pyridine, pyrrole, thienyl, mono-, di-, tri- or tetrazole, mono-, di-, tri- or tetrazine and oxazole. The halogen group includes, for example, fluorine, chlorine, bromine and iodine.

For example, an aromatic system, an alkyl, —CO—R′, —CS—R′, —NO₂, —N(alkyl)₃, N(aromatic)₃, —NH₃⁺, —CN, -halogen, —C(halogen)₃, —NH-alkyl, —NH-aromatic, —NHCO-alkyl, —NHCO-aromatic, —OCO-alkyl, —OCO-aromatic, —N(alkyl)₂ᵣ-N(aromatic)₂, —NH₂, —OH, —O—R′, —SCO-alkyl, —SCO-aromatic, —OCS—R′, —SH, —SO₃H, or —S—R′ may be bonded to the ligand units LE6, LE7 or LE8, where R′ may be hydrogen, alkyl, OH, O-alkyl, SH, S-alkyl, a halogen or an aromatic.

In various embodiments, as already described above, the third organic emitter is a compound of the formula (II) (see also FIG. 5):

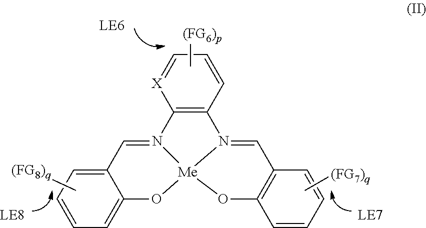

where:

Me is a transition metal, preferably selected from the group consisting of Re, Ru, Os, Co, Rh, Ir, Pd, Pt, Cu, Ag and Au; “X” is C-FG₆, C—H or N;

each FG₆, FG₇, FG₈ group is independently selected from the group consisting of linear or branched C1-C12 alkyl, C2-C12 alkenyl, C2-C12 alkynyl, C3-C8 cycloalkyl, C6-C14 aryl, 5-14-membered heteroaryl in which 1 to 4 ring atoms are independently nitrogen, oxygen or sulphur, 5-14-membered heteroalicyclyl in which 1 to 4 ring atoms are independently nitrogen, oxygen or sulphur, alkylaryl, arylalkyl, alkylheteroaryl, heteroarylalkyl, —Cl, —F, —Br, —I, —CN, C(halogen)₃, —NO₂, —OR, C(O)R, C(O)OR, —OC(O)R, —C(O)NRR′, —NRR′, —N⁺RR′R″, —NR—C(O)R′, —NR—C(O)OR′, —NR—S(O)₂R′, —SR, —S(O)R, —S(O)₂R, —S(O)₂OR, —S(O)₂NRR′, —SC(O)R, —C(S)R, —OC(S)R, —C(S)—NRR′, —NR—C(O)—NR′R″, —PO₃RR′ and —SiRR′R″; or

two adjacent FG₆, FG₇, FG₈ groups in each case, together with the carbon atoms to which they are bonded, form a substituted or unsubstituted cyclic group which is selected from the group consisting of C3-C8 cycloalkyl, C6-C14 aryl, 5-14-membered heteroaryl in which 1 to 4 ring atoms are independently nitrogen, oxygen or sulphur, 5-14-membered heteroalicyclyl in which 1 to 4 ring atoms are independently nitrogen, oxygen or sulphur, where, if the group is substituted, the substituent(s) is/are selected from linear or branched C1-12 alkyl, C2-C12 alkenyl, C2-C12 alkynyl, C3-C8 cycloalkyl, C6-C14 aryl, 5-14-membered heteroaryl in which 1 to 4 ring atoms are independently nitrogen, oxygen or sulphur, 5-14-membered heteroalicyclyl in which 1 to 4 ring atoms are independently nitrogen, oxygen or sulphur, alkylaryl, arylalkyl, heteroarylalkyl and alkylheteroaryl; each R, R′ and R″ is independently selected from the group consisting of hydrogen, linear or branched C1-12 alkyl, C2-C12 alkenyl, C2-C12 alkynyl, C3-C8 cycloalkyl, C6-C14 aryl, 5-14-membered heteroaryl in which 1 to 4 ring atoms are independently nitrogen, oxygen or sulphur, 5-14-membered heteroalicyclyl in which 1 to 4 ring atoms are independently nitrogen, oxygen or sulphur, alkylaryl, arylalkyl, heteroarylalkyl and alkylheteroaryl, or R and R′, if they are bonded to a common nitrogen atom, together with the nitrogen atom form an unsubstituted cyclic group which is selected from the group consisting of 5-14-membered heteroaryl in which 1 to 4 ring atoms are independently nitrogen, oxygen or sulphur and 5-14-membered heteroalicyclyl in which 1 to 4 ring atoms are independently nitrogen, oxygen or sulphur; “p” is an integer from 0 to 3; and each q is independently an integer from 0 to 4.

In various embodiments, the compounds of the formula (I), (Ia) and (II) are unsubstituted, i.e. m, n, o, p and q are 0, i.e. the corresponding positions in the aromatic rings have hydrogen atoms, or are symmetrically substituted in such a way that the compound of the formula (I) or (Ia) bears two identical FG₁, each in the ortho or meta position to the nitrogen bond and/or the compound of the formula (I) or (Ia) in each case bears one, two or more FG₂ and FG₅, where the respective FG₂ and FG₅ substituents at corresponding positions in the particular ring structure are identical and/or the compound of the formula (I) or (Ia) in each case bears one, two or more FG₃ and FG₄, where the respective FG₃ and FG₄ substituents at corresponding positions in the particular ring structure are identical and the compound of the formula (II) bears two identical FG₆, each in the ortho or meta position to the closest nitrogen bond and/or the compound of the formula (II) in each case bears one, two or more FG₇ and FG₈, where the respective FG₇ and FG₈ substituents at corresponding positions in the particular ring structure are identical.

In various embodiments, “l” in formula (I) is 0.

In various embodiments, “X” in formula (II) is C—H.

In various embodiments, all FG₂ and all FG₅ are hydrogen. In various embodiments, C6-14 aryl is selected from: phenyl and naphthyl. In various embodiments, heteroaryl is selected from: 2-thiophenyl, 3-thiophenyl, 2-pyridinyl, 3-pyridinyl, 4-pyridinyl, 1-pyrrolyl, 2-pyrrolyl, 3-pyrrolyl, 1-pyrrolidinyl, 1-morpholinyl, 2-benzothiophenyl, thienyl, mono-, di-, tri- and tetrazolyl, mono-, di-, tri- and tetrazinyl, and oxazolyl. In various embodiments of the compound of the formula (I) or (Ia), preferably (I), all FG₁ are hydrogen.

In other embodiments of the compound of the formula (I) or (Ia), preferably (I), m is 1, 2 or 3 and FG₁ is selected from the group consisting of methyl, ethyl, t-butyl, methoxy, N-carbazolyl, N,N-diphenylamine. When FG₁ is N-carbazolyl or N,N-diphenylamine, m is preferably 1 and FG₁ is in the para position. When FG₁ is methyl, m is preferably 1, 2 or 3, where the methyl radical is preferably in the para position when m=1, the methyl radicals are preferably each in the meta position when m=2, and the three methyl radicals are preferably in the 2, 4 and 6 positions when m=3. When FG₁ is t-butyl, m is preferably 2 and the two t-butyl radicals are preferably in the meta position. When FG₁ is ethyl, m is preferably 1 and FG₁ is preferably in the para position. When FG₁ is methoxy, m is preferably 1 and the radical is preferably in the ortho position.

In various embodiments of the compound of the formula (I) or (Ia), preferably (I), all FG₃ and all FG₄ are hydrogen.

In other embodiments of the compound of the formula (I) or (Ia), preferably (I), each “o” is 1 and FG₃ and FG₄ are identical and are selected from the group consisting of methyl and t-butyl. When FG₃ and FG₄ are methyl, they are preferably in the 3 or 4 position (meta or para position relative to the coordinating nitrogen or carbon atom). When FG₃ and FG₄ are t-butyl, they are preferably in the 4 position (para position relative to the coordinating nitrogen or carbon atom).

In various embodiments of the compound of the formula (II), all FG₆ are hydrogen.

In other embodiments of the compound of the formula (II), “p” is 2 or 4 and two FG₆ in each case are adjacent to one another (when m=2 in the 3 and 4 positions, and when m=4 in the 2, 3, 4 and 5 positions) and two FG₆ in each case together form an aromatic ring, preferably a phenyl ring, fused to the ring to which they are bonded (when m=2 at the 3 and 4 positions, when m=4 at the 2 and 3 positions or the 4 and 5 positions).

In various embodiments of the compound of the formula (II), each “q” is 1 or 2 and FG₇ and FG₈ are identical. In embodiments of this kind, FG₇ and FG₈ are selected from the group consisting of hydrogen, methyl, t-butyl, ethenyl, ethynyl, phenyl, 2-tetrahydrothiophenyl, nitro, fluoro, chloro, bromo, iodo, N-morpholinyl, 2-furanyl, 2-pyridinyl, 2-benzothiophenyl, methoxy, phenoxy, benzyloxy, 2-pyridininyloxy, acetoxy, benzoate, formyl, acetyl, acyl, preferably C12-acyl, t-butylcarboxyl, cyclohexylcarboxyl, phenylcarboxyl, benzylcarboxyl, thiomethyl, thio-t-butyl, thiophenyl, thiobenzyl, thio-2-benzothiophenyl, —S(O)-Me, —S(O)2-4-methylphenyl, N,N-dimethylamino, N-phenyl-N-naphthylamino, N-benzylamino, —NH—C(O)-t-butyl, —NH—C(O)— phenyl, —NH—C(O)—O-phenyl, —NH—C(O)—O-t-butyl, —NH—C(O)—O-benzyl, —NH—S(O)2-4-methylphenyl, —C(O)—NH-methyl, —C(S)—N(methyl)2, —NH—C(O)—NH-phenyl, —P(O)(OEt)2, —Si(Me)2(t-butyl) and cyano. When q=1, the t-butyl, ethenyl, phenyl, 2-tetrahydrothiophenyl, fluoro, iodo, N-morpholinyl, 2-furanyl, 2-pyridinyl, 2-benzothiophenyl, methoxy, phenoxy, benzyloxy, 2-pyridinyloxy, acetoxy, benzoate, thiomethyl, thio-t-butyl, thiobenzyl, thio-2-benzothiophenyl, —S(O)-Me, —S(O)2-4-methylphenyl, N,N-dimethylamino, N-phenyl-N-naphthylamino, N-benzylamino, —NH—C(O)-t-butyl, —NH—C(O)— phenyl, —NH—C(O)—O-phenyl, —NH—C(O)—O-t-butyl, —NH—S(O)2-4-methylphenyl, —NH—C(O)—NH-phenyl, —P(O)(OEt)2 and —Si(Me)2(t-butyl) radicals are each preferably in the para position relative to the coordinating oxygen. When q=1, the formyl, acetyl, acyl, preferably C12-acyl, t-butylcarboxyl, cyclohexylcarboxyl, phenylcarboxyl, benzylcarboxyl, —C(O)—NH— methyl, —C(S)—N(methyl)2, cyano, nitro and bromo radicals are preferably each in the meta position relative to the coordinating oxygen. When q=1, the ethynyl, thiophenyl, —NH—C(O)-benzyl and chloro radicals are each preferably in the ortho position relative to the coordinating oxygen. When q=2, the Me, t-butyl and methoxy radicals are in the ortho and para positions relative to the coordinating oxygen, and the fluoro radicals are in the meta position relative to the coordinating oxygen. Alternatively, two FG₇ and two FG₈, in each case together, form a phenyl, 1,4-dioxane or 1,3-dioxolane ring. In the latter case, the two FG₇ or the two FG₈ are in the 3 and 4 positions or 4 and 5 positions.

In various embodiments, the third organic emitters are selected from those disclosed in the international patent publication WO 2005/112520 A1, which are incorporated herein by reference in their entirety.

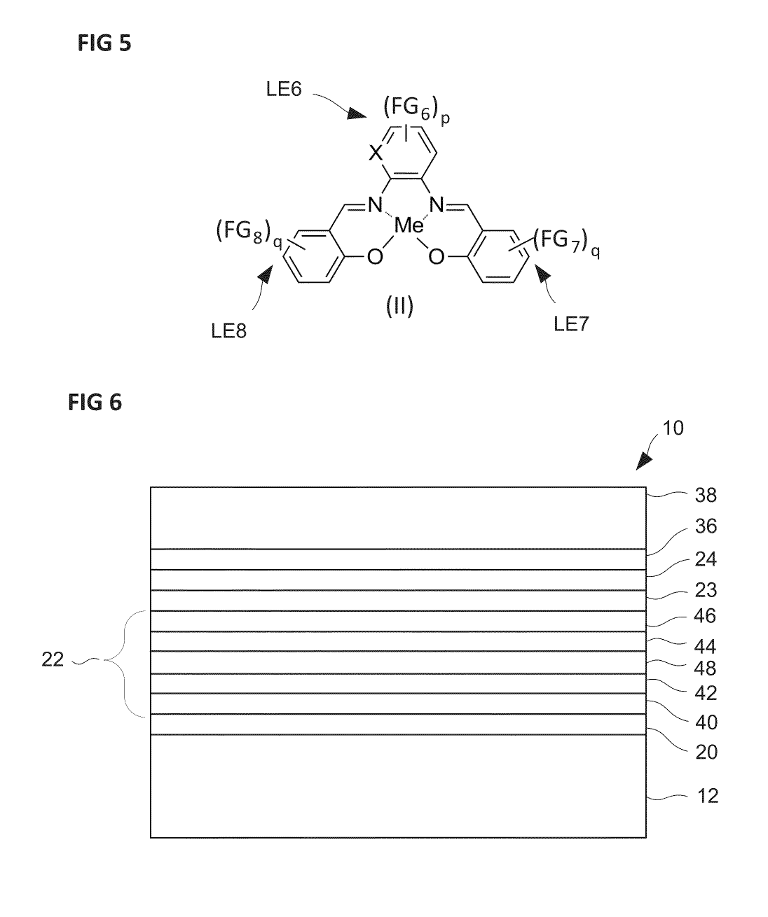

FIG. 6 shows a detailed section diagram of a layer structure of a working example of an organic light-emitting component 10 which may largely correspond, for example, to the organic light-emitting component 10 elucidated above. More particularly, the organic light-emitting component 10 may include the first emitter layer 42. In addition, the organic light-emitting component 10 may include a second emitter layer 44. Moreover, the organic light-emitting component 10 includes the first, the second and the third organic emitter as described above.

The organic light emitting component 10 optionally has a first interlayer 48 between the first emitter layer 42 and the second emitter layer 44. The first interlayer 48 may be configured as an intermediate electrode or as a charge carrier generation layer structure (CGL). The intermediate electrode may be electrically connected to an external voltage source. The external voltage source may provide, for example, a third electrical potential at the intermediate electrode. However, the intermediate electrode may also not have an external electrical connection, for example by virtue of the intermediate electrode having a floating electrical potential.

For example, the first emitter layer 42 includes the first organic emitter and the second emitter layer 44 includes the second organic emitter and the third organic emitter. Alternatively, the first emitter layer 42 includes the first organic emitter and the second organic emitter, and the second emitter layer 44 includes the third organic emitter. Alternatively, the first emitter layer 42 includes the first organic emitter and the third organic emitter, and the second emitter layer 44 includes the second organic emitter. In addition, the first emitter layer 42 may be formed above or below the second emitter layer 44.

The emitter layer 42, 44 which includes the emitters which emit in the green and in the red may be referred to as yellow unit, and the other emitter layer 42, 44 can be referred to as blue unit. The blue unit is positioned in the optical cavity at the first maximum for blue, and the yellow unit is positioned at the second cavity maximum. By means of mixing of the various colours of light, the result is the emission of light with a white colour impression. Optionally, it is possible to dispense with the first interlayer 48 and for the first emitter layer 42 directly adjoin the second emitter layer 44.

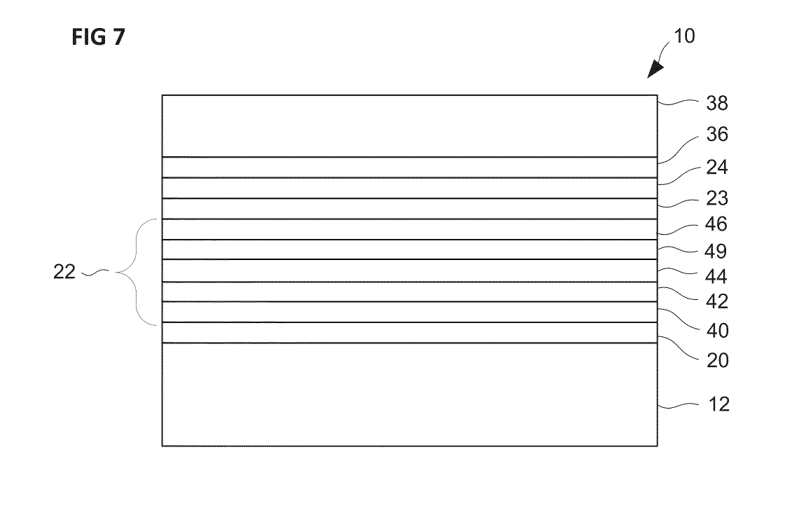

FIG. 7 shows a detailed section diagram of a layer structure of a working example of an organic light-emitting component 10 which may largely correspond, for example, to the organic light-emitting component 10 elucidated above. More particularly, the organic light-emitting component 10 may include the first emitter layer 42 and the second emitter layer 44 as described above, and especially the first, second and third organic emitters as described above. The first emitter layer 42 may be disposed above or below the second emitter layer 44. In addition, a third emitter layer 49 is formed. The third emitter layer 49 may be formed above, below or between the first and second emitter layers 42, 44. The third emitter layer 49 may include the first, second and/or third organic emitters.

The organic light emitting component 10 may optionally have the first interlayer 48 between the first emitter layer 42 and the second emitter layer 44. The first interlayer 48 may be configured as an intermediate electrode or charge carrier generation layer structure (CGL). Optionally, the organic light-emitting component 10 may have a second interlayer (not shown) between the first emitter layer 42 and the third emitter layer 49 or between the second emitter layer 44 and the third emitter layer 49. The second interlayer may be configured as an intermediate electrode or charge carrier generation layer structure (CGL).

In the above-elucidated organic light-emitting components 10, the second organic emitter which emits in the green may be disposed in one of the emitter layers 42, 44, 49. The third organic emitter which emits in the red may be disposed in another of the emitter layers 42, 44, 49. The first organic emitter which emits in the blue may be disposed in yet another of the emitter layers 42, 44, 49.

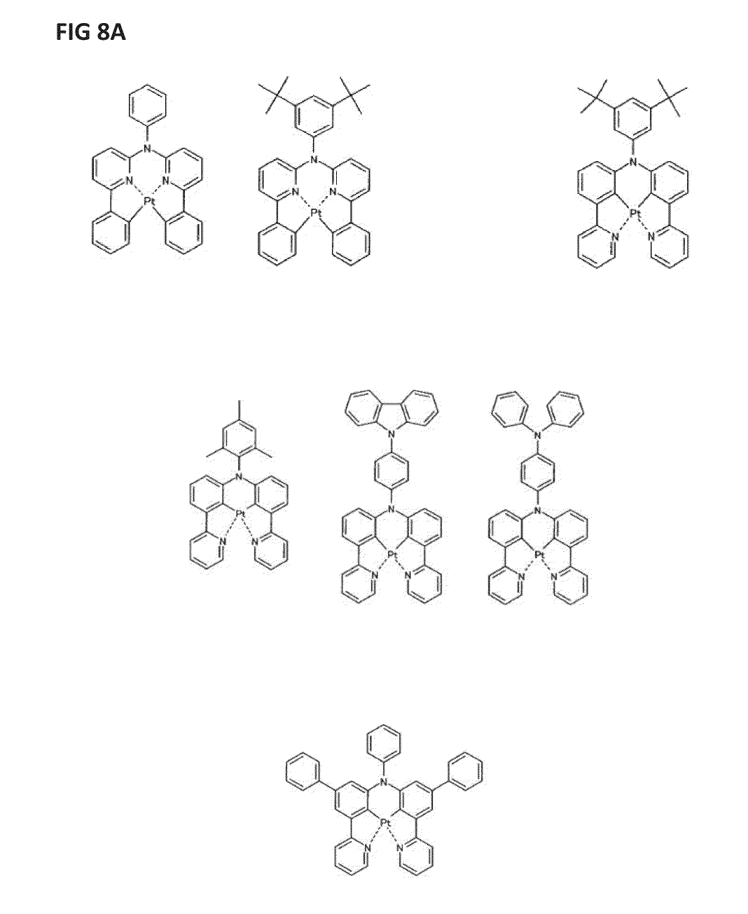

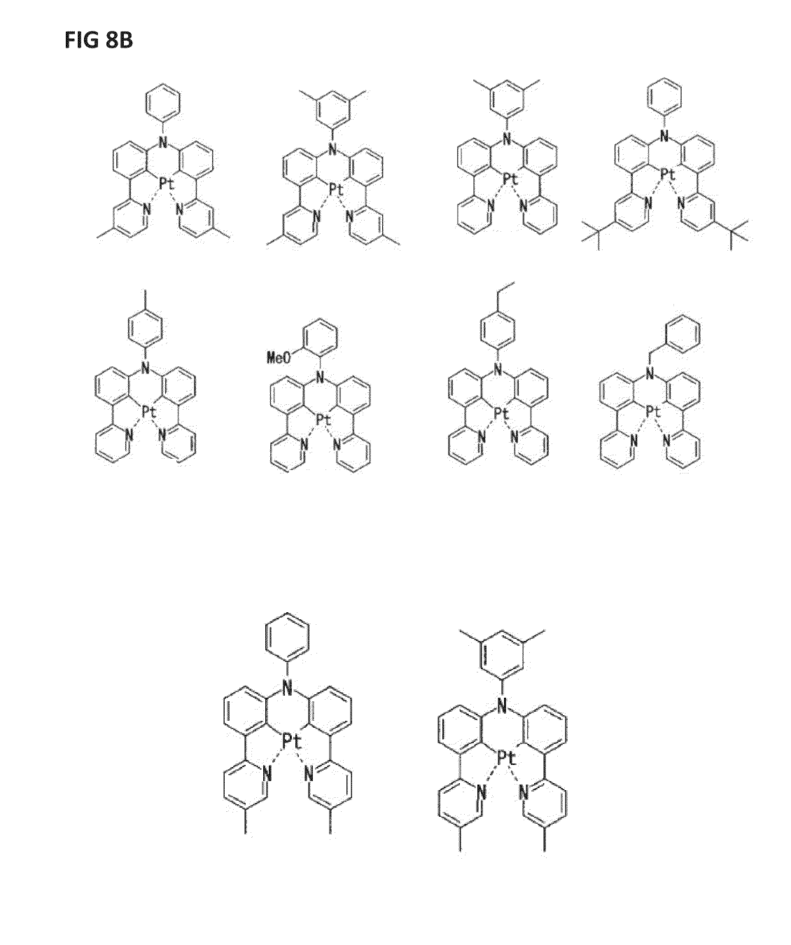

FIGS. 8A and 8B show working examples of third organic emitters, each of which may be disposed in one of the emitter layers 42, 44, 49 of one of the organic light-emitting components 10 elucidated above.

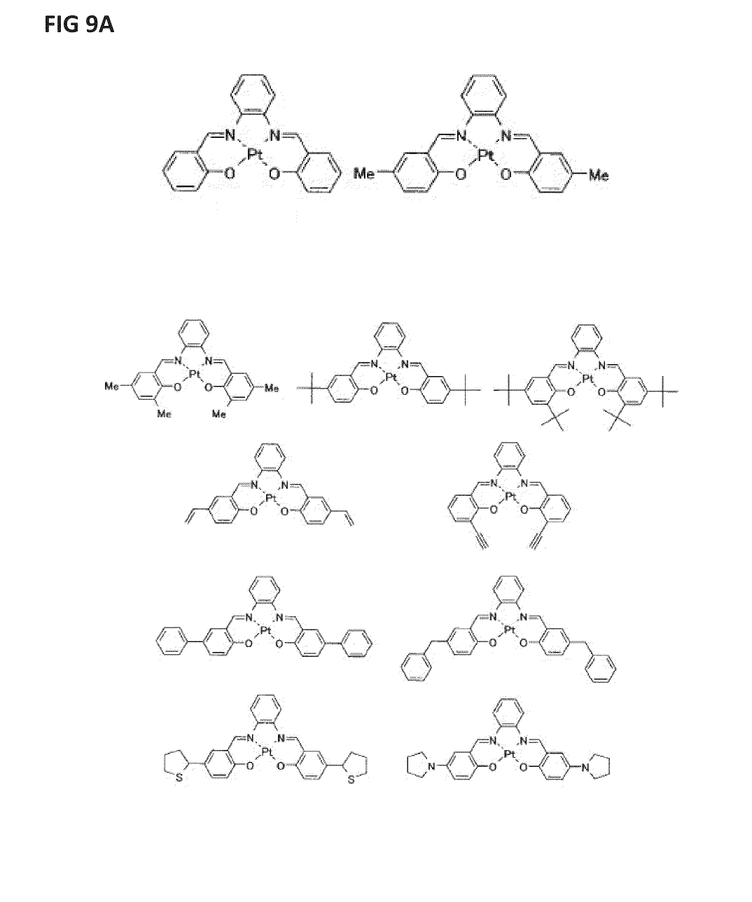

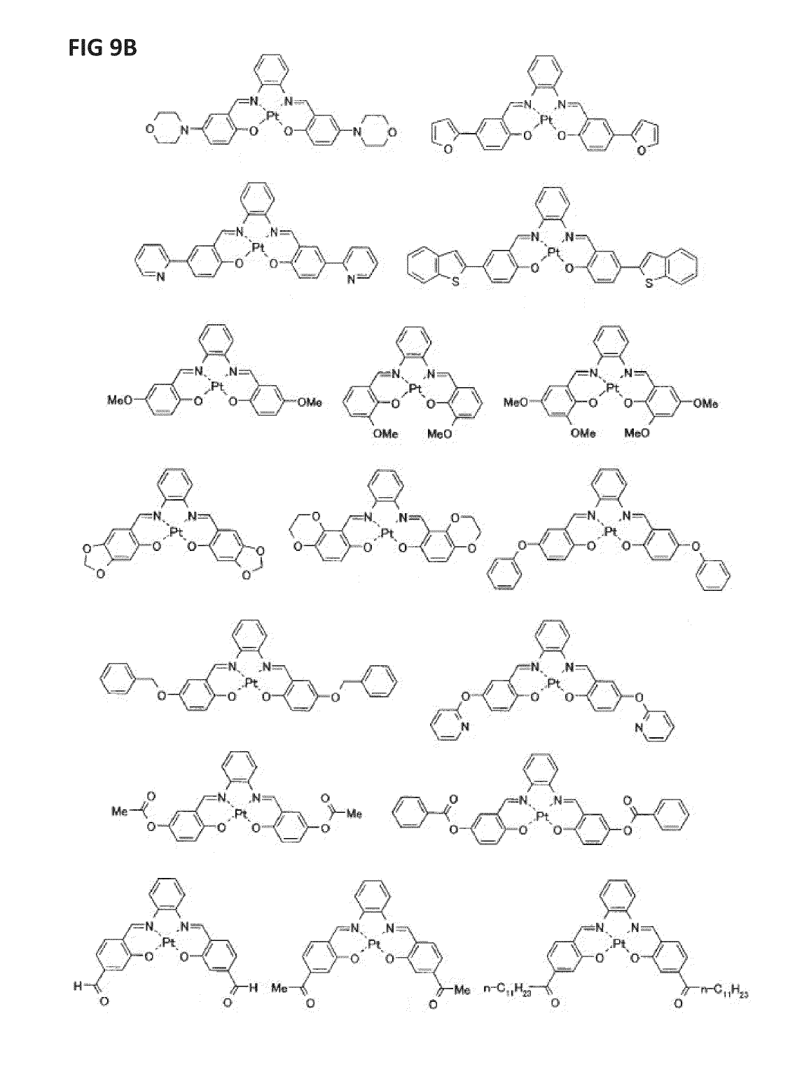

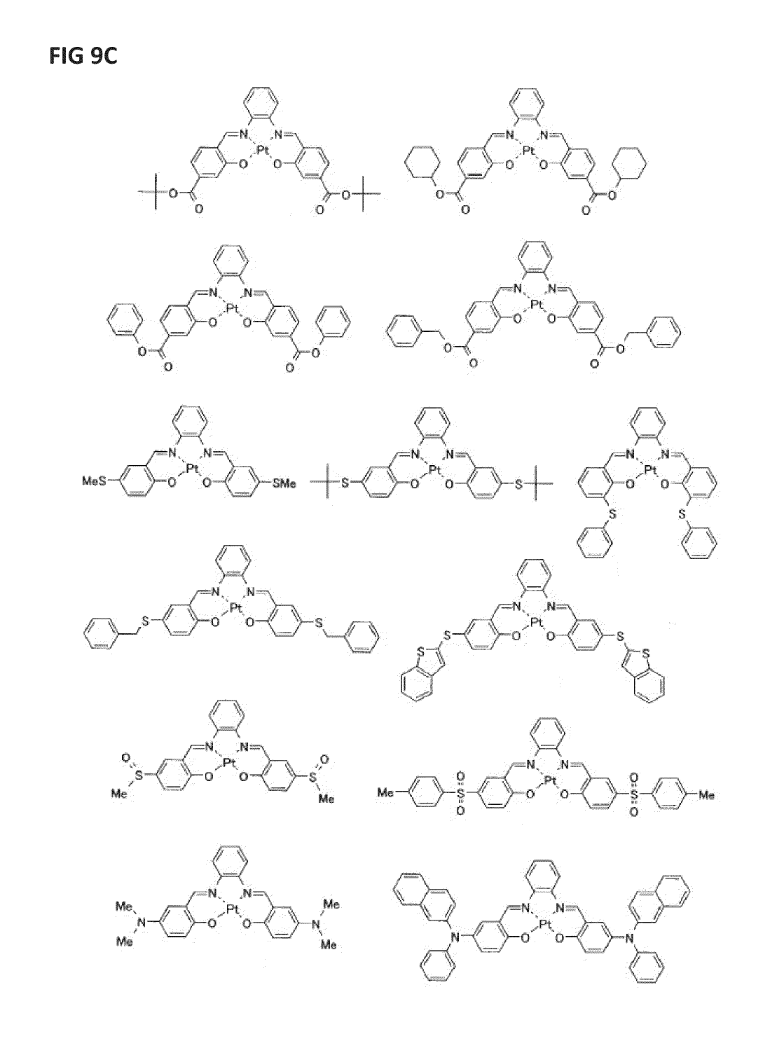

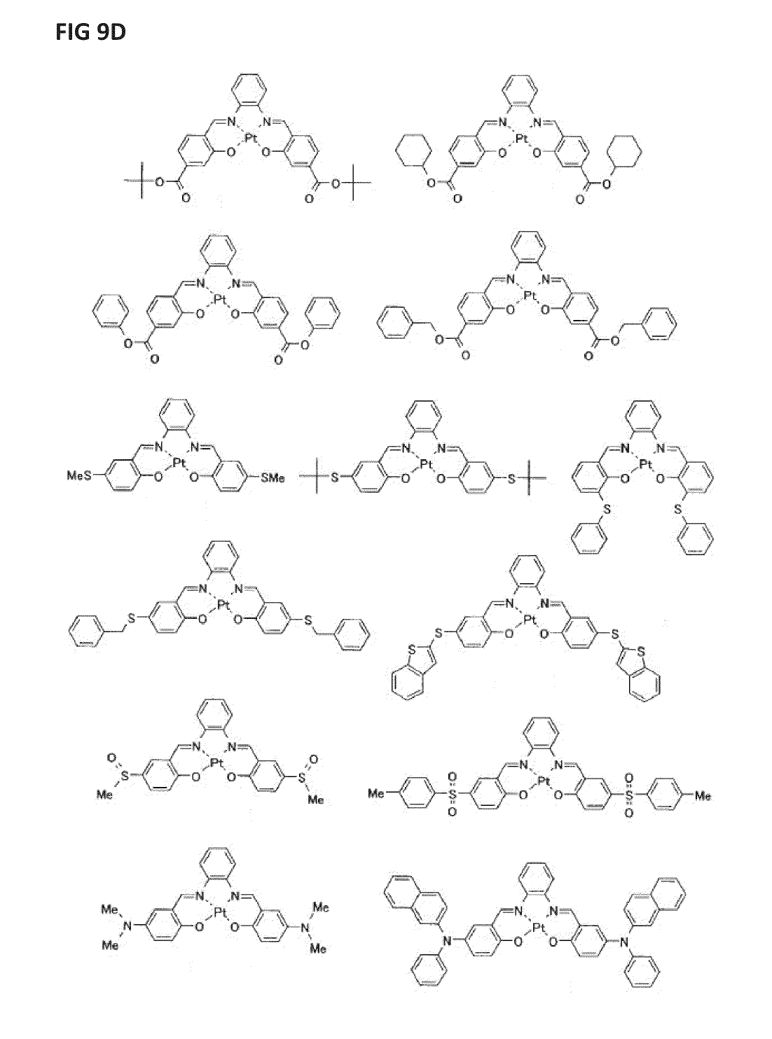

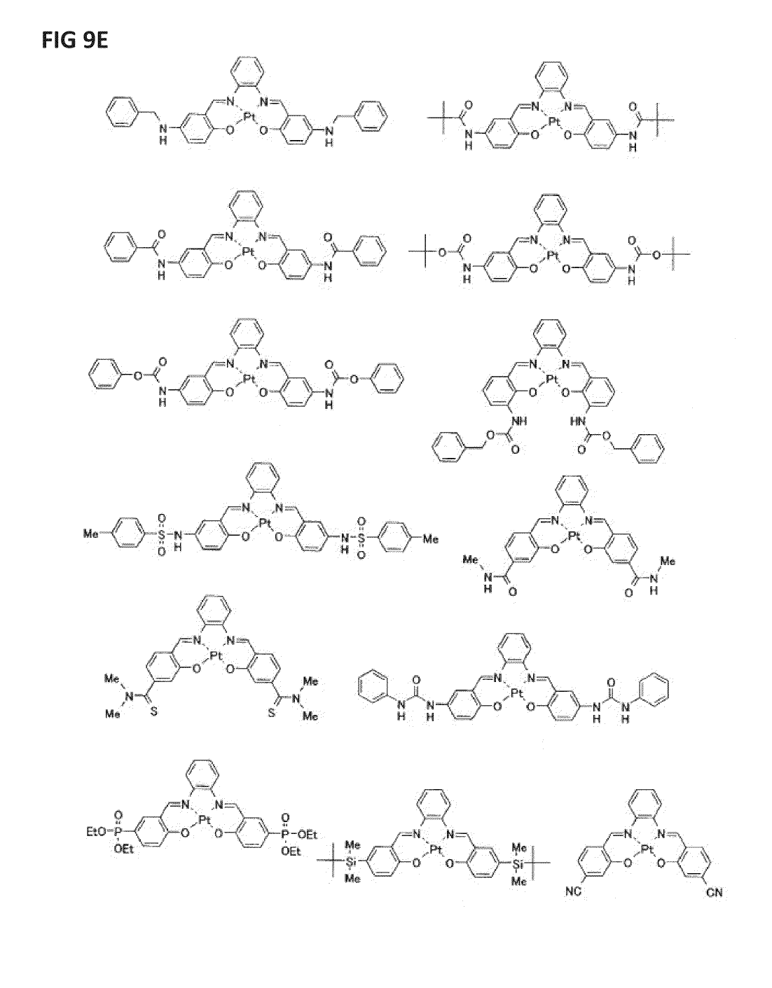

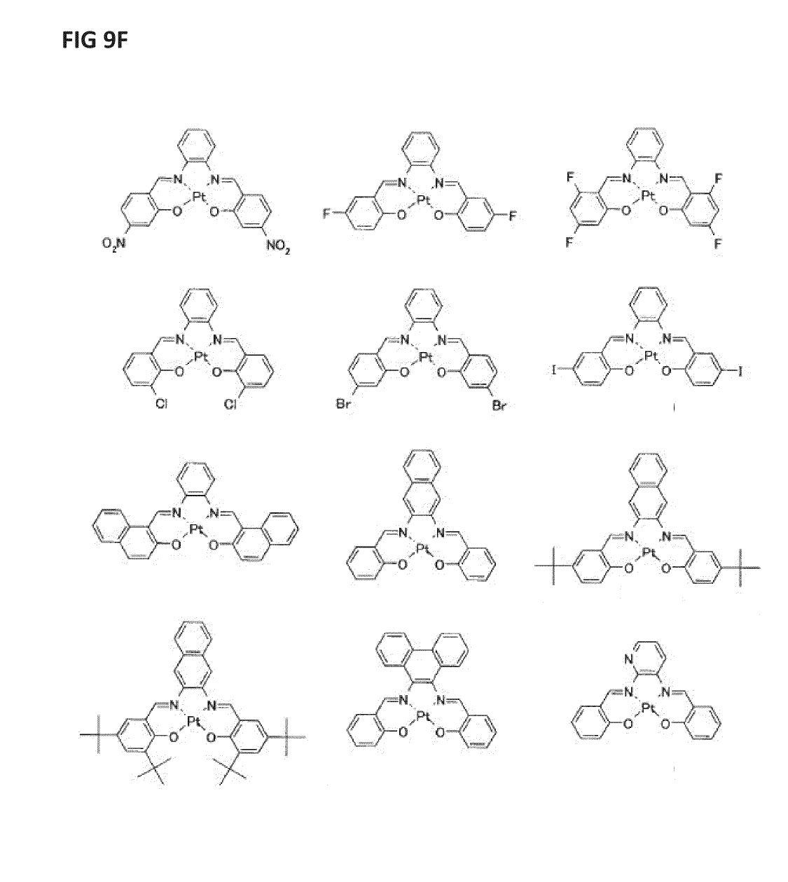

FIGS. 9A, 9B, 9C, 9D, 9E, 9F show working examples of third organic emitters, each of which may be disposed in one of the emitter layers 42, 44, 49 of one of the organic light-emitting components 10 elucidated above.

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

1. Organic light-emitting component comprising:
a carrier,
a first electrode above the carrier,
an organic functional layer structure above the first electrode, and
a second electrode above the organic functional layer structure,
wherein the organic functional layer structure includes first organic emitters that emit in the blue spectral region, second organic emitters that emit in the green spectral region and third organic emitters that emit in the red spectral region, wherein the third organic emitters include a molecule having at least one ligand having ligand units, and wherein the third organic emitters have the property that, on emission of light, a charge transfer takes place from one of the ligand units of one of the molecules to another of the ligand units of the same molecule and the corresponding singlet-triplet splitting is small.

2. Organic light-emitting component according to claim 1, wherein the singlet-triplet splitting of the third organic emitter is within a range between 0.05 eV and 0.3 eV.

3. Organic light-emitting component according to claim 2, wherein the singlet-triplet splitting of the third organic emitter is within a range between 0.1 eV and 0.2 eV.

4. Organic light-emitting component according to claim 3, wherein the singlet-triplet splitting of the third organic emitter is about 0.25 eV.

5. Organic light-emitting component according to claim 1, wherein at least one of the ligand units has at least one aromatic group and at least one group bonded thereto.

6. Organic light-emitting component according to claim 5, wherein the at least one group is an alkyl group, an aromatic group, a halogen group, an alkenyl group or hydrogen.

7. Organic light-emitting component according to claim 5, wherein the third organic emitter is a compound of the formula (I) or (Ia) 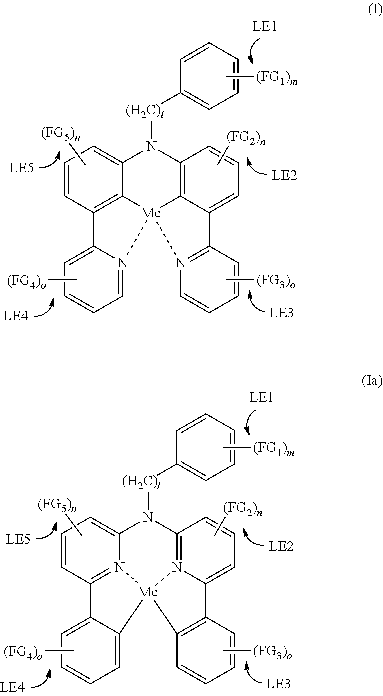
where
Me is a transition metal, preferably selected from the group consisting of Re, Ru, Os, Co, Rh, Ir, Pd, Pt, Cu, Ag and Au;
each FG₁ to FG₅ group is independently selected from the group consisting of linear or branched C1-C12 alkyl, C2-C12 alkenyl, C2-C12 alkynyl, C3-C8 cycloalkyl, C6-C14 aryl, 5-14-membered heteroaryl in which 1 to 4 ring atoms are independently nitrogen, oxygen or sulphur, 5-14-membered heteroalicyclyl in which 1 to 4 ring atoms are independently nitrogen, oxygen or sulphur, alkylaryl, arylalkyl, alkylheteroaryl, heteroarylalkyl, —Cl, —F, —Br, —I, —CN, C(halogen)₃, —NO₂, —OR, —C(O)R, —C(O)OR, —OC(O)R, —C(O)NRR′, —NRR′, —N⁺RR′R″, —NR—C(O)R′, —NR—C(O)OR′, —NR—S(O)₂R′, —SR, —S(O)R, —S(O)₂R, —S(O)₂OR, —S(O)₂NRR′, —SC(O)R, —C(S)R,
—OC(S)R, —C(S)—NRR′, —NR—C(O)—NR′R″, —PO₃RR′ and —SiRR′R″; or two adjacent FG₁, FG₂, FG₃, FG₄, FG₅ groups in each case, together with the carbon atoms to which they are bonded, form a substituted or unsubstituted cyclic group which is selected from the group consisting of C3-C8 cycloalkyl, C6-C14 aryl, 5-14-membered heteroaryl in which 1 to 4 ring atoms are independently nitrogen, oxygen or sulphur, 5-14-membered heteroalicyclyl in which 1 to 4 ring atoms are independently nitrogen, oxygen or sulphur, where, if the group is substituted, the substituent(s) is/are selected from linear or branched C1-12 alkyl, C2-C12 alkenyl, C2-C12 alkynyl, C3-C8 cycloalkyl, C6-C14 aryl, 5-14-membered heteroaryl in which 1 to 4 ring atoms are independently nitrogen, oxygen or sulphur, 5-14-membered heteroalicyclyl in which 1 to 4 ring atoms are independently nitrogen, oxygen or sulphur, alkylaryl, arylalkyl, heteroarylalkyl and alkylheteroaryl;
each R, R′ and R″ is independently selected from the group consisting of hydrogen, linear or branched C1-12 alkyl, C2-C12 alkenyl, C2-C12 alkynyl, C3-C8 cycloalkyl, C6-C14 aryl, 5-14-membered heteroaryl in which 1 to 4 ring atoms are independently nitrogen, oxygen or sulphur, 5-14-membered heteroalicyclyl in which 1 to 4 ring atoms are independently nitrogen, oxygen or sulphur, alkylaryl, arylalkyl, heteroarylalkyl and alkylheteroaryl, or R and R′, if they are bonded to a common nitrogen atom, together with the nitrogen atom form an unsubstituted cyclic group which is selected from the group consisting of 5-14-membered heteroaryl in which 1 to 4 ring atoms are independently nitrogen, oxygen or sulphur and 5-14-membered heteroalicyclyl in which 1 to 4 ring atoms are independently nitrogen, oxygen or sulphur;
“l” is 0, 1 or 2;
“m” is an integer from 0 to 5;
each “n” is an integer from 0 to 3; and
each “o” is an integer from 0 to 4.

8. Organic light-emitting component according to claim 5, in which the third organic emitter is a compound of the formula (II) 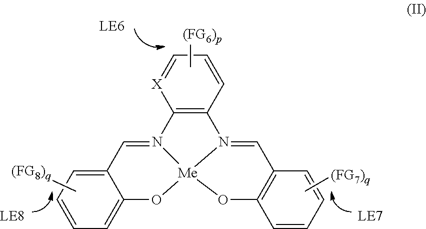
where
Me is a transition metal, preferably selected from the group consisting of Re, Ru,
Os, Co, Rh, Ir, Pd, Pt, Cu, Ag and Au;
“X” is C-FG₆, C—H or N;
each FG₆, FG_{A}, FG₈ group is independently selected from the group consisting of linear or branched C1-C12 alkyl, C2-C12 alkenyl, C2-C12 alkynyl, C3-C8 cycloalkyl, C6-C14 aryl, 5-14-membered heteroaryl in which 1 to 4 ring atoms are independently nitrogen, oxygen or sulphur, 5-14-membered heteroalicyclyl in which 1 to 4 ring atoms are independently nitrogen, oxygen or sulphur, alkylaryl, arylalkyl, alkylheteroaryl, heteroarylalkyl, —Cl, —F, —Br, —I, —CN, C(halogen)₃, —NO₂, —OR, —C(O)R, —C(O)OR, —OC(O)R, —C(O)NRR′, —NRR′, —N⁺RR′R″, —NR—C(O)R′, —NR—C(O)OR′, —NR—S(O)₂R′, —SR, —S(O)R, —S(O)₂R, —S(O)₂OR, —S(O)₂NRR′, —SC(O)R, —C(S)R,
—OC(S)R, —C(S)—NRR′, —NR—C(O)—NR′R″, —PO₃RR′ and —SiRR′R″ or two adjacent FG₆, FG_{A}, FG₈ groups in each case, together with the carbon atoms to which they are bonded, form a substituted or unsubstituted cyclic group which is selected from the group consisting of C3-C8 cycloalkyl, C6-C14 aryl, 5-14-membered heteroaryl in which 1 to 4 ring atoms are independently nitrogen, oxygen or sulphur, 5-14-membered heteroalicyclyl in which 1 to 4 ring atoms are independently nitrogen, oxygen or sulphur, where, if the group is substituted, the substituent(s) is/are selected from linear or branched C1-12 alkyl, C2-C12 alkenyl, C2-C12 alkynyl, C3-C8 cycloalkyl, C6-C14 aryl, 5-14-membered heteroaryl in which 1 to 4 ring atoms are independently nitrogen, oxygen or sulphur, 5-14-membered heteroalicyclyl in which 1 to 4 ring atoms are independently nitrogen, oxygen or sulphur, alkylaryl, arylalkyl, heteroarylalkyl and alkylheteroaryl;
each R, R′ and R″ is independently selected from the group consisting of hydrogen, linear or branched C1-12 alkyl, C2-C12 alkenyl, C2-C12 alkynyl, C3-C8 cycloalkyl, C6-C14 aryl, 5-14-membered heteroaryl in which 1 to 4 ring atoms are independently nitrogen, oxygen or sulphur, 5-14-membered heteroalicyclyl in which 1 to 4 ring atoms are independently nitrogen, oxygen or sulphur, alkylaryl, arylalkyl, heteroarylalkyl and alkylheteroaryl, or R and R′, if they are bonded to a common nitrogen atom, together with the nitrogen atom form an unsubstituted cyclic group which is selected from the group consisting of 5-14-membered heteroaryl in which 1 to 4 ring atoms are independently nitrogen, oxygen or sulphur and 5-14-membered heteroalicyclyl in which 1 to 4 ring atoms are independently nitrogen, oxygen or sulphur;
“p” is an integer from 0 to 3; and
each “q” is independently an integer from 0 to 4.

9. Organic light-emitting component according to claim 7, where
(1) in the compounds of the formula (I) or (Ia), all m, n and o are each 0 or, in the compounds of the formula (II), all p and q are each 0;
(2) the compounds of the formula (I) or (Ia) are symmetrically substituted in such a way that
(a) the compound of the formula (I) or (Ia) bears two identical FG₁, each in the ortho or meta position to the nitrogen bond; and/or
(b) the compound of the formula (I) or (Ia) in each case bears one, two or more FG₂ and FG₅, where the respective FG₂ and FG₅ substituents at corresponding positions in the particular ring structure are identical; and/or
(c) the compound of the formula (I) or (Ia) in each case bears one, two or more FG₃ and FG₄, where the respective FG₃ and FG₄ substituents at corresponding positions in the particular ring structure are identical; or
(3) the compounds of the formula (II) are symmetrically substituted in such a way that
(a) the compound of the formula (II) bears two identical FG₆, each in the ortho or meta position to the nitrogen bond; and/or
(b) the compound of the formula (II) in each case bears one, two or more FG₇ and FG₈, where the respective FG₇ and FG₈ substituents at corresponding positions in the particular ring structure are identical.

10. Organic light-emitting component according to claim 1, wherein the organic functional layer structure has a first emitter layer including at least one of the organic emitters, a second emitter layer including at least one of the organic emitters, and/or a third emitter layer including at least one of the organic emitters.

11. Organic light-emitting component according to claim 10, wherein a first interlayer is formed between the first emitter layer and the second emitter layer and/or wherein a second interlayer is formed between the second emitter layer and the third emitter layer.

12. Organic light-emitting component according to claim 10, wherein the emitter layers include one of the organic emitters.

13. Organic light-emitting component according to claim 10, wherein at least one of the emitter layers includes two of the organic emitters.

14. Organic light-emitting component according to claim 10, wherein at least one of the emitter layers includes three of the organic emitters.

15. Organic light-emitting component according to claim 1, which emits white light.
